(19) United States
(12) Patent Application Publication
(10) Pub. No.: US 2025/0324888 A1
(43) Pub. Date: Oct. 16, 2025

(54) DISPLAY DEVICE AND METHOD OF MANUFACTURING THE SAME

(71) Applicant: Samsung Display Co., LTD., Yongin-si (KR)

(72) Inventors: Soo Dong KIM, Yongin-si (KR); Jun Hyuk WOO, Yongin-si (KR); Ree Hyang KIM, Yongin-si (KR); Je Won YOO, Yongin-si (KR)

(73) Assignee: Samsung Display Co., LTD., Yongin-si (KR)

(21) Appl. No.: 18/973,643

(22) Filed: Dec. 9, 2024

(30) Foreign Application Priority Data
Apr. 15, 2024 (KR) 10-2024-0049957

(51) Int. Cl. H10K 59/80; H01L 25/16; H10H 29/01; H10H 29/37; H10H 29/853; H10K 59/12; H10K 59/122; H10K 59/70

(52) U.S. Cl. CPC H10K 59/873; H10H 29/0362; H10H 29/37; H10H 29/853; H10K 59/1201; H10K 59/122; H10K 59/70; H01L 25/167; H10H 29/012

(57) ABSTRACT

A display device may include a substrate, a plurality of light emitting elements disposed on the substrate and generating light, and a bank portion disposed on the substrate, protruding from the substrate, and adjacent to at least one of the plurality of light emitting elements. The plurality of light emitting elements may include a first light emitting element generating light of a first color and including an inorganic material, and a second light emitting element generating light of a second color different from the first color, the second light emitting element may include an organic material, and the bank portion may be disposed between the first light emitting element and the second light emitting element.

### CROSS-REFERENCE TO RELATED APPLICATION(S)

This application claims priority under 35 U.S.C. § 119 to and benefits of Korean Patent Application No. 10-2024-0049957 filed on Apr. 15, 2024 in the Korean Intellectual Property Office, the entire contents of which are incorporated herein by reference.

### BACKGROUND

### 1. Technical Field

The disclosure relates to a hybrid display device including two different types of light emitting elements and a method of manufacturing the hybrid display device.

### 2. Description of the Related Art

Recently, as interest in an information display has increased, research and development on a display device is continuously being conducted.

### SUMMARY

An object to be solved by the disclosure is to provide a display device that may prevent damage to an organic light emitting element in a hybrid display device.

Another object to be solved by the disclosure is to provide a method of manufacturing the display device.

The objects of the disclosure are not limited to the object described above, and other technical objects which are not described will be clearly understood by those skilled in the art from the description below.

According to embodiments of the disclosure, a display device may include a substrate, a plurality of light emitting elements disposed on the substrate and generating light, and a bank portion disposed on the substrate, protruding from the substrate, and adjacent to at least one of the plurality of light emitting elements. The plurality of light emitting elements may include a first light emitting element generating light of a first color and including an inorganic material, and a second light emitting element generating light of a second color different from the first color, the second light emitting element including an organic material, and the bank portion may be disposed between the first light emitting element and the second light emitting element.

In an embodiment, the display device may further include an encapsulation layer covering the plurality of light emitting elements, and the encapsulation layer may include a first encapsulation layer covering the second light emitting element and including an organic material, and a second encapsulation layer covering the first light emitting element.

In an embodiment, the bank portion may surround the first encapsulation layer in a plan view.

In an embodiment, the first encapsulation layer may define an opening overlapping the first light emitting element, and the bank portion may be disposed around the opening.

In an embodiment, the display device may further include a first capping layer disposed on the bank portion, the first capping layer may be disposed under the first encapsulation layer and under the second encapsulation layer, and a second capping layer disposed on the first capping layer and the first encapsulation layer, the second capping layer may be disposed under the second encapsulation layer.

In an embodiment, the first capping layer may extend along a surface shape of the bank portion, and the second capping layer may extend along a surface shape of the first capping layer on the bank portion.

In an embodiment, a contact area between the first capping layer and the second capping layer in an area may be greater than a planar area of the area where the bank portion may be disposed.

In an embodiment, the bank portion may include a first bank having a continuous shape.

In an embodiment, the bank portion may further include a second bank disposed on at least one of an inside and an outside of the first bank.

In an embodiment, the second bank may include two or more sub banks, and the two or more sub banks may be spaced apart from each other.

In an embodiment, the display device may further include a filling layer filling a groove between the first bank and the second bank.

In an embodiment, the filling layer may include at least one material selected from an inorganic oxide and a complex compound.

According to embodiments, a method of manufacturing a display device may include forming a bank portion protruding from a substrate on the substrate, and forming a plurality of light emitting elements at a position adjacent to the bank portion on the substrate, the forming of the plurality of light emitting elements may include forming a first light emitting element including an inorganic material that generates light of a first color, and forming a second light emitting element including an organic material that generates light of a second color different from the first color, and the first light emitting element and the second light emitting element may be formed with the bank portion disposed therebetween.

In an embodiment, the method may further include forming a first encapsulation layer on the second light emitting element and the bank portion after the forming of the second light emitting element and before the forming of the first light emitting element, and removing the first encapsulation layer in an area spaced apart from the second light emitting element by the bank portion after the forming of the second light emitting element and before the forming of the first light emitting element.

In an embodiment, the method may further include forming a second encapsulation layer on the first light emitting element after the forming of the first light emitting element.

In an embodiment, the method may further include forming a first capping layer on the second light emitting element and the bank portion before the forming of the first encapsulation layer, and the first capping layer may cover a surface of the bank portion.

In an embodiment, the method may further include forming a second capping layer on the first encapsulation layer and on the first capping layer before the firming of the first light emitting element, and the second capping layer may cover the first capping layer that is disposed on the bank portion.

In an embodiment, the forming of the bank portion may include forming a first bank having a continuous shape.

In an embodiment, the forming of the bank portion may further include forming a second preliminary bank disposed on at least one of an inside and an outside of the first bank, and forming a second bank by partially removing the second preliminary bank.

In an embodiment, the method may further include forming a filling layer filling a groove between the first bank and the second bank after the forming of the first capping layer and before the forming of the second capping layer.

Specific details of other embodiments are included in the detailed description and drawings.

According to the above-described embodiment, the display device may include the first light emitting element which is a light emitting element including an inorganic material, the second light emitting element which is a light emitting element including an organic material, and a bank portion disposed between the first light emitting element and the second light emitting element. Since the bank portion has a shape protruding from the substrate, and the first capping layer and the second capping layer extend along a surface shape of the bank portion on the bank portion, the contact area between the first capping layer and the second capping layer on the partition may increase. Accordingly, a penetration distance of moisture and oxygen from an outside to an inside of the display panel may increase. Therefore, damage to an organic light emitting element due to penetration of external moisture and oxygen may be prevented.

An effect according to embodiments is not limited to the content described above, and further various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating an embodiment of a display device;

FIG. 2 is a schematic block diagram illustrating an embodiment of one of sub-pixels of FIG. 1;

FIG. 3 is a schematic plan view illustrating an embodiment of a display panel of FIG. 1;

FIG. 4 is a schematic plan view illustrating an embodiment of one of multiple pixels in FIG. 3;

FIG. 5 is a schematic cross-sectional view taken along line I-I′ of FIG. 4;

FIG. 6 is a schematic cross-sectional view according to an embodiment of FIG. 5;

FIG. 7 is a schematic plan view according to an embodiment of FIG. 4;

FIG. 8 is a schematic cross-sectional view taken along line II-II′ of FIG. 7;

FIG. 9 is a schematic plan view according to an embodiment of FIG. 4;

FIG. 10 is a schematic cross-sectional view taken along line III-III′ of FIG. 9;

FIG. 11 is a schematic plan view according to an embodiment of FIG. 9;

FIG. 12 is a schematic cross-sectional view taken along line IV-IV′ of FIG. 11;

FIG. 13 is a schematic plan view according to still an embodiment of FIG. 9;

FIG. 14 is a schematic plan view according to an embodiment of FIG. 4;

FIG. 15 is a schematic plan view illustrating an embodiment of one of the plurality of pixels of FIG. 3;

FIG. 16 is a schematic cross-sectional view taken along line V-V′ of FIG. 15;

FIGS. 17 to 29 are schematic cross-sectional views illustrating a method of manufacturing a display device according to embodiments;

FIGS. 30 to 34 are schematic cross-sectional views according to an embodiment of FIGS. 17 to 29;

FIGS. 35 and 36 are schematic cross-sectional views according to still an embodiment of FIGS. 17 to 29; and

FIGS. 37 to 39 are schematic plan views according to an embodiment of FIGS. 17 to 29

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

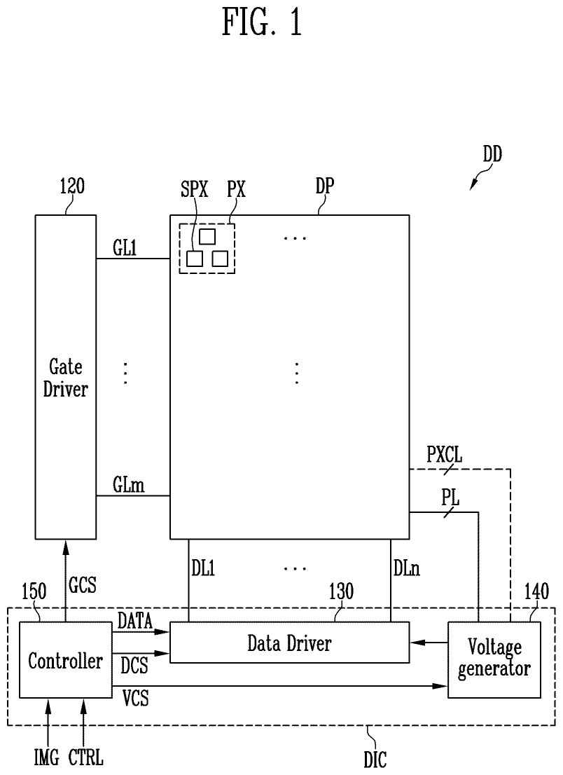

FIG. 1 is a schematic block diagram illustrating an embodiment of a display device.

Referring to FIG. 1, the display device DD may include a display panel DP, a gate driver 120, a data driver 130, a voltage generator 140, and a controller 150.

The display panel DP includes sub-pixels SPX. The sub-pixels SPX may be connected to the gate driver 120 through first to m-th gate lines GL1 to GLm. The sub-pixels SPX may be connected to the data driver 130 through first to n-th data lines DL1 to DLn.

The sub-pixels SPX may generate light of two or more colors. For example, each of the sub-pixels SPX may generate light such as red, green, blue, cyan, magenta, or yellow.

Two or more sub-pixels among the sub-pixels SPX may configure a pixel (e.g., single pixel) PX. For example, the pixel PX may include three sub-pixels as shown in FIG. 1. As described above, the pixel PX may emit light of various colors and various luminances according to a combination of light emitted from the sub-pixels SPX included in the pixel PX.

The gate driver 120 may be connected to the sub-pixels SPX arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be disposed on a side (e.g., single side) of the display panel DP. However, embodiments are not limited thereto. For example, the gate driver 120 may be divided into two or more physically and/or logically divided drivers, and the drivers may be disposed on a side (e.g., single side) of the display panel DP and another side of the display panel DP opposite the side (e.g., single side). As described above, the gate driver 120 may be disposed around the display panel DP in various shapes according to embodiments.

The data driver 130 may be connected to the sub-pixels SPX arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SPX may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device DD, such as the gate driver 120, the data driver 130, and the controller 150. The voltage generator 140 may generate the plurality of voltages by receiving an input voltage from an outside of the display device DD and regulating the received voltage.

The voltage generator 140 may generate a first power voltage and a second power voltage. The generated first and second power voltages may be provided to the sub-pixels SPX through power lines PL. In another embodiment, at least one of the first and second power voltages may be provided from the outside of the display device DD.

The voltage generator 140 may provide various voltages and/or signals. For example, the voltage generator 140 may provide one or more initialization voltages applied to the sub-pixels SPX. For example, during a sensing operation for sensing electrical characteristics of transistors and/or light emitting elements of the sub-pixels SPX, a reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SPX, and the voltage generator 140 may generate the pixel control signals. In embodiments, the voltage generator 140 may provide the pixel control signals to the sub-pixels SPX through pixel control lines PXCL. In FIG. 1, the pixel control lines PXCL may be connected between the voltage generator 140 and the display panel DP, but embodiments are not limited thereto. For example, the pixel control lines PXCL may be connected between the gate driver 120 and the display panel DP. The pixel control signals may be transmitted from the voltage generator 140 to the pixel control lines PXCL through the gate driver 120.

The controller 150 controls overall operations of the display device DD. The controller 150 receives input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG may be suitable for the display device DD or the display panel DP and output the image data DATA. In embodiments, the controller 150 may output the image data DATA by aligning the input image data IMG so that the input image data IMG is suitable for the sub-pixels SPX of a row portion.

Two or more components of the data driver 130, the voltage generator 140, and the controller 150 may be mounted on an integrated circuit (e.g., single integrated circuit). As shown in FIG. 1, the data driver 130, the voltage generator 140, and the controller 150 may be included in a driver integrated circuit DIC. The data driver 130, the voltage generator 140, and the controller 150 may be functionally divided components in a driver (e.g., single driver) integrated circuit DIC. In other embodiments, at least one of the data driver 130, the voltage generator 140, and the controller 150 may be provided as a component distinguished from the driver integrated circuit DIC.

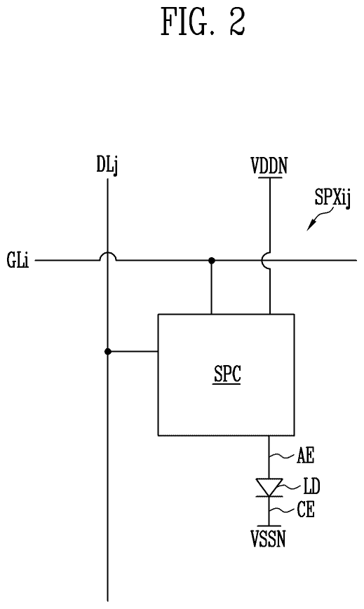

FIG. 2 is a schematic block diagram illustrating an embodiment of one of the sub-pixels of FIG. 1. In FIG. 2, among the sub-pixels SPX of FIG. 1, a sub-pixel SPXij arranged in an i-th row (i may be an integer greater than or equal to 1 and less than or equal to m) and a j-th column (j may be an integer greater than or equal to 1 and less than or equal to n) may be shown as an example.

Referring to FIG. 2, the sub-pixel SPXij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and receive the first power voltage. The second power voltage node VSSN may be connected to another one of the power lines PL of FIG. 1 and receives the second power voltage. The first power voltage may have a voltage level higher than that of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL of FIG. 1. The sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon, a polycrystalline silicon semiconductor, an oxide semiconductor, and the like.

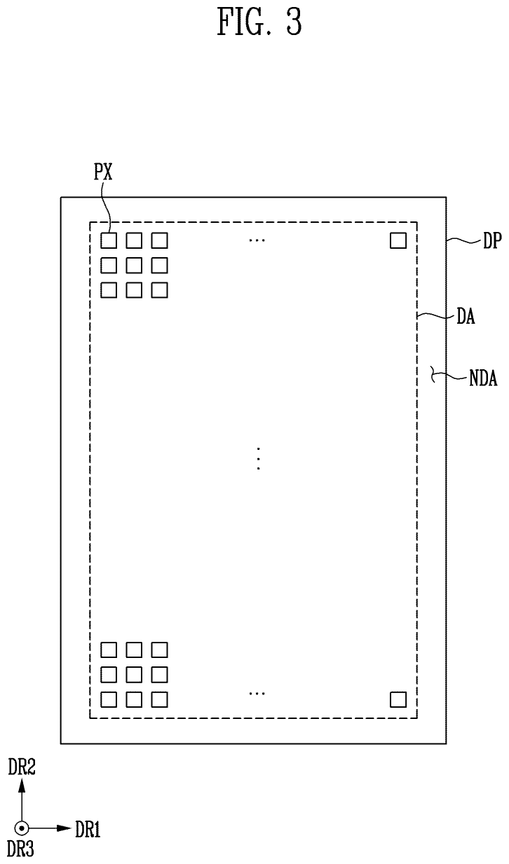

FIG. 3 is a schematic plan view illustrating an embodiment of the display panel of FIG. 1.

Referring to FIG. 3, the display panel DP may include a display area DA and a non-display area NDA. The display panel DP displays an image through the display area DA. The non-display area NDA may be disposed around the display area DA.

The display panel DP includes multiple pixels PX in the display area DA. The plurality of pixels PX may be arranged in a first direction DR1 and a second direction DR2 intersecting the first direction DR1. For example, the plurality of pixels PX may be arranged in a matrix form in the first direction DR1 and the second direction DR2. As an example, the plurality of pixels PX may be arranged in a zigzag form in the first direction DR1 and the second direction DR2. An arrangement of the plurality of pixels PX may vary according to embodiments. The first direction DR1 may be a column direction, and the second direction DR2 may be a row direction.

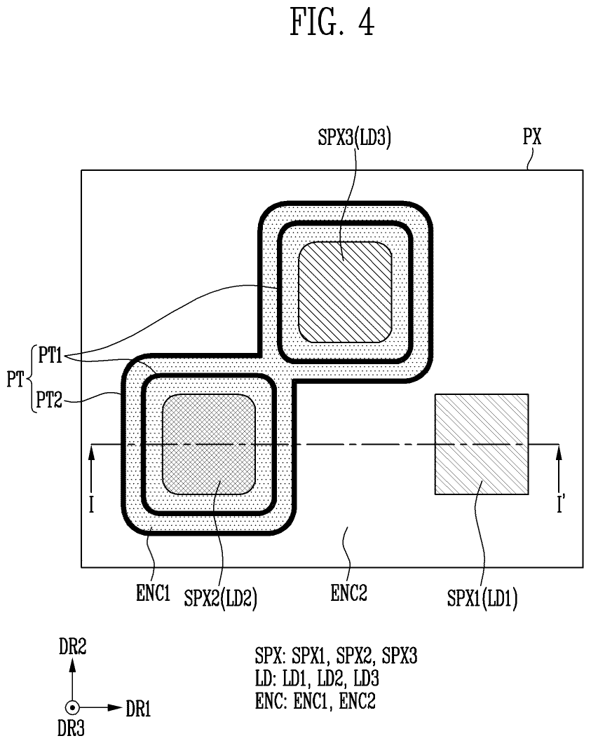

One pixel PX may include two or more sub-pixels (for example, the sub-pixel SPX of FIG. 4). Hereinafter, the pixel PX may be shown as including three sub-pixels (for example, sub-pixels SPX1, SPX2, and SPX3 of FIG. 4), but embodiments are not limited thereto. For example, the pixel PX may include two sub-pixels. Hereinafter, for convenience of description, it is assumed that the pixel PX includes first to third sub-pixels.

As the display panel DP, a light emitting diode display panel (LED display panel) using a micro scale or nano scale of light emitting diode as a light emitting element, and a display panel capable of self-emission such as an organic light emitting display panel (OLED panel) using an organic light emitting diode as a light emitting element, and a hybrid display panel using a micro scale or nano scale of light emitting diode and an organic light emitting diode together as a light emitting element may be used.

A component for controlling the pixels PX may be disposed in the non-display area NDA. Lines connected to the pixels PX, for example, the first to m-th gate lines GL1 to GLm of FIG. 1, the first to n-th data lines DL1 to DLn, the power lines PL, and the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. The data driver 130, the voltage generator 140, and the controller 150 may be implemented as a driver integrated circuit DIC of FIG. 1, separate from the display panel DP, and the driver integrated circuit DIC may be connected to the lines disposed in the non-display area NDA. In other embodiments, the gate driver 120 may be implemented as an integrated circuit (e.g., single integrated circuit) separate from the display panel DP, together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like.

In embodiments, the display panel DP may have a substantially flat display surface. In other embodiments, the display panel DP may have a display surface that is at least partially round. In embodiments, the display panel DP may be bendable, foldable, or rollable. In such cases, the display panel DP and/or a substrate of the display panel DP may include materials having a flexible property.

FIG. 4 is a schematic plan view illustrating an embodiment of one of the plurality of pixels of FIG. 3.

Referring to FIG. 4, the pixel PX may include the first to third sub-pixels SPX1, SPX2, and SPX3. A center of each of the first to third sub-pixels SPX1, SPX2, and SPX3 may configure a triangular structure. For example, the second sub-pixel SPX2 may be positioned in the first direction DR1 from the first sub-pixel SPX1, and the third sub-pixel SPX3 may be positioned in the second direction DR2 from a center between the first sub-pixel SPX1 and the second sub-pixel SPX2. However, an arrangement of the pixel PX is not limited thereto and may vary according to embodiments. For example, the first to third sub-pixels SPX1, SPX2, and SPX3 may be arranged in the first direction DR1.

Each of the first to third sub-pixels SPX1, SPX2, and SPX3 may generate light of one of various colors such as red, green, blue, cyan, magenta, and yellow. Hereinafter, for clear and concise description, it is assumed that the first sub-pixel SPX1 may be configured to generate light of a blue color, the second sub-pixel SPX2 may be configured to generate light of a red color, and the third sub-pixel SPX3 may be configured to generate light of a green color.

Each of the first to third sub-pixels SPX1, SPX2, and SPX3 may include at least one light emitting element LD configured to generate light. In embodiments, first to third light emitting elements LD1, LD2, and LD3 of the first to third sub-pixels SPX1, SPX2, and SPX3 may respectively generate light of different colors. For example, the first to third light emitting elements LD1, LD2, and LD3 of the first to third sub-pixels SPX1, SPX2, and SPX3 may generate the light of the blue color, the red color, and the green color, respectively. In other embodiments, the first to third light emitting elements LD1, LD2, and LD3 of the first to third sub-pixels SPX1, SPX2, and SPX3 may generate light of the same color. For example, the light emitting elements of the first to third sub-pixels SPX1, SPX2, and SPX3 may generate the light of the blue color.

In embodiments, the first light emitting element LD1 may be an inorganic light emitting element including an inorganic material. The second and the third light emitting elements LD2 and LD3 may be organic light emitting elements including an organic material. For example, in the pixel PX1, the first light emitting element LD1 generating the light of the blue color may include an inorganic light emitting element, and each of the second light emitting element LD2 generating the light of the red color and the third light emitting element LD3 generating the light of the green color may include an organic light emitting element. Accordingly, the pixel PX1 may include both an inorganic light emitting element and an organic light emitting element so that emission efficiency may be maximized for each color.

In embodiments, the pixel PX1 may further include a bank portion (or partition wall portion) PT disposed between the first light emitting element LD1 and the second and third light emitting elements LD2 and LD3. For example, the bank portion PT may surround the second light emitting element LD2 and the third light emitting element LD3. Therefore, the first light emitting element LD1 and the second and third light emitting elements LD2 and LD3 may be isolated from each other by the bank portion PT.

The bank portion PT may include one or more banks. At this time, at least one of the banks may have a continuous shape. For example, the bank portion PT may include a first bank (or first partition wall) PT1 and a second bank (or second partition wall) PT2 disposed outside the first bank PT1 and surrounding the first bank PT1. At this time, an inside may refer to a direction facing the sub-pixel SPX based on the first bank PT1, and an outside may refer to a direction opposite to the direction facing the sub-pixel SPX based on the first bank PT1. Each of the first bank PT1 and the second bank PT2 may have a continuous shape. For example, each of the first bank PT1 and the second bank PT2 may surround at least one of the second and third light emitting elements LD2 and LD3 without a broken portion. However, the disclosure is not limited thereto, and in other embodiments, one of the first bank PT1 and the second bank PT2 may have a partially removed (or broken or discontinuous) shape.

For example, the first bank PT1 may surround each of the second and third light emitting elements LD2 and LD3, and the second bank PT2 may extend while entirely surrounding the second and third light emitting elements LD2 and LD3.

The pixel PX may include an encapsulation layer ENC covering the plurality of light emitting elements LD. The encapsulation layer ENC may include a first encapsulation layer ENC1 covering the second and third light emitting elements LD2 and LD3 and a second encapsulation layer ENC2 covering the first light emitting element LD1. In embodiments, the bank portion PT may surround the first encapsulation layer ENC1 in a plan view. For example, the bank portion PT may surround the second and third light emitting elements LD2 and LD3 in a schematic plan view, and the first encapsulation layer ENC1 may be positioned in the bank portion PT and may overlap the second and third light emitting elements LD2 and LD3.

In embodiments, the first encapsulation layer ENC1 and the second encapsulation layer ENC2 may be disposed with the bank portion PT disposed between the first encapsulation layer ENC1 and the second encapsulation layer ENC2 in a plan view. For example, the bank portion PT may be positioned at an interface between the first encapsulation layer ENC1 and the second encapsulation layer ENC2.

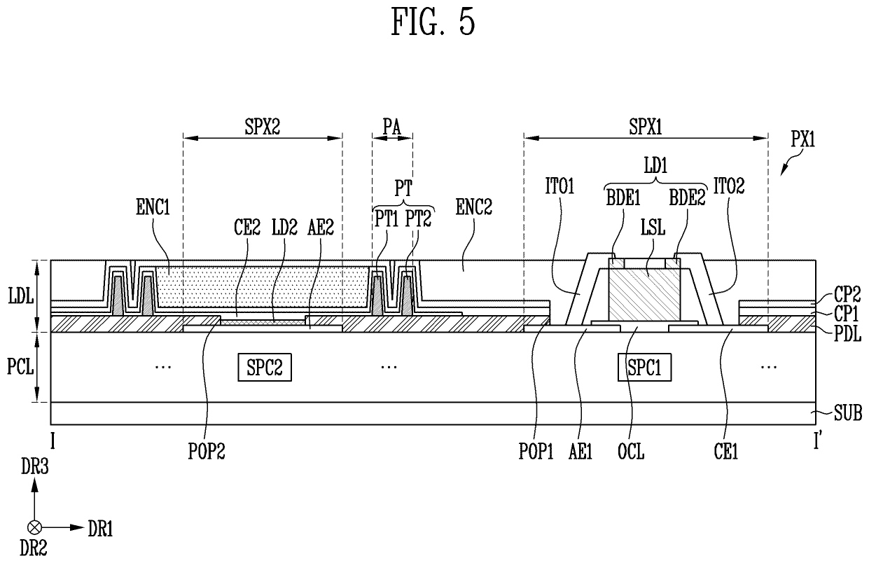

FIG. 5 is a schematic cross-sectional view taken along line I-I′ of FIG. 4. Hereinafter, for convenience of description, the disclosure is described based on only the first and second sub-pixels SPX1 and SPX2. In this discussion, it is assumed that the third sub-pixel SPX3 has the same structure as the second sub-pixel SPX2 except for a color of emitted light.

Referring to FIGS. 3 to 5, the display panel DP may include a substrate SUB, a pixel circuit layer PCL, and a light emitting element layer sequentially stacked on each other and on the substrate SUB in a third direction DR3 intersecting the first and second directions DR1 and DR2.

The substrate SUB may be formed of an insulating material such as glass or resin. For example, the substrate SUB may include a glass substrate. As an example, the substrate SUB may include a polyimide (PI) substrate. As still an example, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, lines, and the like.

The circuit elements of the pixel circuit layer PCL may include the sub-pixel circuits SPC1 and SPC2 of each of the sub-pixels SPX of FIG. 3. In other words, the circuit elements of the pixel circuit layer PCL may be provided as transistors and one or more capacitors of the sub-pixel circuits SPC1 and SPC2.

The lines of the pixel circuit layer PCL may include lines connected to the sub-pixels SPX. The lines of the pixel circuit layer PCL may include various signal lines and/or voltage lines desired to drive the light emitting element layer LDL.

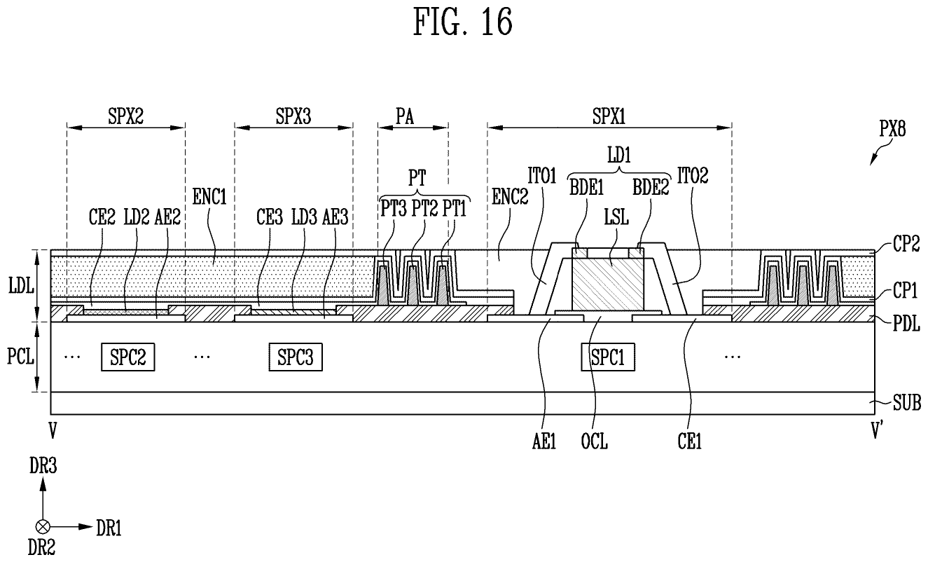

The light emitting element layer LDL may be disposed on the pixel circuit layer PCL. The light emitting element layer LDL may include the light emitting elements LD1 and LD2 of the sub-pixels SPX. Specifically, the light emitting element layer LDL may include a first anode electrode AE1, a first cathode electrode CE1, an overcoat layer OCL, the first light emitting element LD1, first and second transparent electrodes ITO1 and ITO2, a second anode electrode AE2, the second light emitting element LD2, a second cathode electrode CE2, a pixel defining layer PDL, a first capping layer CP1, a first encapsulation layer ENC1, a second capping layer CP2, and a second encapsulation layer ENC2. As later illustrated in FIG. 16, the light emitting layer LDL may also include a third anode AE3, third light emitting element LD3, and third cathode electrode CE3.

The first anode electrode AE1, the first cathode electrode CE1, and the second anode electrode AE2 may be disposed on the pixel circuit layer PCL.

The first anode electrode AEl may be electrically connected to the first sub-pixel circuit SPC1 included in the pixel circuit layer PCL. As described above, the first anode electrode AE1 may be electrically connected to a transistor included in the first sub-pixel circuit SPC1.

The first cathode electrode CE1 may be spaced apart from the first anode electrode AE1 in the first direction DR1. The first cathode electrode CE1 may be electrically connected to the second power voltage node VSSN of FIG. 2. Accordingly, the second power voltage applied to the second power voltage node VSSN may be transmitted to the first cathode electrode CE1.

The second anode electrode AE2 may be electrically connected to the second sub-pixel circuit SPC2 included in the pixel circuit layer PCL. As described above, the second anode electrode AE2 may be electrically connected to a transistor included in the second sub-pixel circuit SPC2.

The pixel defining layer PDL may be disposed on the first anode electrode AE1, the first cathode electrode CE1, and the second anode electrode AE2. The pixel defining layer PDL may define pixel openings POP1 and POP2 exposing portions of the first anode electrode AE1, the first cathode electrode CE1, and the second anode electrode AE2. The first light emitting element LD1 may be disposed in the first pixel opening POP1 of the pixel defining layer PDL. The second light emitting element LD2 may be disposed in the second pixel opening POP2 of the pixel defining layer PDL. As described above, the pixel defining layer PDL may define an area where the first light emitting element LD1 and the second light emitting element LD2 may be positioned.

The pixel defining layer PDL may be configured to include a light blocking material to prevent light mixing between adjacent sub-pixels SPX. In embodiments, the pixel defining layer PDL may include an organic material. For example, the pixel defining layer PDL may include an organic insulating material such as acryl resin, epoxy resin, phenol resin, polyamide resin, polyimide resin, and a combination thereof.

The overcoat layer OCL may be disposed in the first pixel opening POP1 of the pixel defining layer PDL on the first anode electrode AE1 and the first cathode electrode CE1. The first light emitting element LD1 may be disposed on the overcoat layer OCL.

The overcoat layer OCL may fix the first light emitting element LD1 so that the first light emitting element LD1 does not move. The overcoat layer OCL may protect components disposed under the overcoat layer OCL from a foreign material such as dust and moisture. For example, the overcoat layer OCL may include at least one of an inorganic insulating layer and an organic insulating layer. For example, the overcoat layer OCL may include epoxy, but embodiments are not limited thereto.

The first light emitting element LD1 may emit the light of the blue color and may include an inorganic material. For example, the first light emitting element LD1 may be an inorganic light emitting element. The first light emitting element LD1 may include a first semiconductor layer, an active layer, a second semiconductor layer, and an auxiliary layer. The first light emitting element LD1 includes a light emitting stack LSL in which the auxiliary layer, the first semiconductor layer, the active layer, and the second semiconductor layer may be sequentially stacked on each other.

The first light emitting element LD1 includes first and second bonding electrodes BDE1 and BDE2 facing in the same direction (for example, the third direction DR3). The first light emitting element LD1 may be a lateral chip type of light emitting element.

The second encapsulation layer ENC2 covering the first light emitting element LD1 may be disposed on the first light emitting element LD1. The second encapsulation layer ENC2 may overlap the first light emitting element LD1 and may be spaced apart from the second light emitting element LD2. The second encapsulation layer ENC2 may protect components disposed under the second encapsulation layer ENC2 and provide a substantially flat upper surface.

The second encapsulation layer ENC2 may include an inorganic insulating layer including an inorganic material and/or an organic insulating layer including an organic material. The inorganic insulating layer may include, for example, at least one material such as silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

First and second transparent electrodes ITO1 and ITO2 may be disposed on the second encapsulation layer ENC2. The first transparent electrode ITO1 may be electrically connected to the exposed first anode electrode AE1 through a contact hole defined in the second encapsulation layer ENC2. The second transparent electrode ITO2 may be electrically connected to the exposed first cathode electrode CE1 through another contact hole defined in the second encapsulation layer ENC2. Accordingly, the first bonding electrode BDE1 may be electrically connected to the first anode electrode AE1 through the first transparent electrode ITO1. The second bonding electrode BDE2 may be electrically connected to the first cathode electrode CE1 through the second transparent electrode ITO2.

In embodiments, the first and second transparent electrodes ITO1 and ITO2 may be configured to be substantially transparent or translucent to satisfy a light transmittance. In embodiments, the first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, a material of the first and second transparent electrodes ITO1 and ITO2 are not limited thereto.

The first sub-pixel circuit SPC1, the first light emitting element LD1, the first anode electrode AE1, the first cathode electrode CE1, the first transparent electrode ITO1, and the second transparent electrode ITO2 may configure the first sub-pixel SPX1.

On the second anode electrode AE2, the second light emitting element LD2 may be disposed in the second pixel opening POP2 of the pixel defining layer PDL.

The second light emitting element LD2 may emit the light of the red color and may include an organic material. For example, the second light emitting element LD2 may be an organic light emitting element. The second light emitting element LD2 may have a multilayer structure including a hole injection layer, a hole transport layer, an organic light emitting layer, an electron transport layer, and an electron injection layer.

On the pixel defining layer PDL, the bank portion PT protruding from the pixel defining layer PDL in the third direction DR3 may be disposed between the first light emitting element LD1 and the second light emitting element LD2. Therefore, the bank portion PT may isolate the first light emitting element LD1 and the second light emitting element LD2. In embodiments, the bank portion PT may include an inorganic insulating layer including an inorganic material and/or an organic insulating layer including an organic material.

The bank portion PT may include the first bank PT1 and the second bank PT2 disposed outside the first bank PT1. In FIG. 5, the respective first bank PT1 and second bank PT2 have the same height, the same shape, and the same width, and include a same material, but embodiments are not limited thereto. For example, the respective first bank PT1 and second bank PT2 may have different heights, different shapes, different widths, and different materials.

The second cathode electrode CE2 may be disposed on the pixel defining layer PDL, the bank portion PT, and the second light emitting element LD2. The second cathode electrode CE2 may be disposed on the second light emitting element LD2 through the second pixel opening POP2 and may overlap the second light emitting element LD2. The second cathode electrode CE2 may continuously extend in an area where the second sub-pixel SPX2 and the third sub-pixel SPX3 may be disposed excluding an area where the first sub-pixel SPX1 may be disposed across the plurality of pixels PX1.

The second cathode electrode CE2 may be electrically connected to the second power voltage node VSSN of FIG. 2. Accordingly, the second power voltage applied to the second power voltage node VSSN may be transmitted to the second cathode electrode CE2.

The second sub-pixel circuit SPC2, the second light emitting element LD2, the second anode electrode AE2, and the second cathode electrode CE2 may configure the second sub-pixel SPX2.

The first capping layer CP1 may be disposed on the second cathode electrode CE2. The first capping layer CP1 may define an opening overlapping the first pixel opening POP1. The first light emitting element LD1 may be disposed in the opening. The first capping layer CP1 may protect components under the first capping layer CP1, such as the second light emitting element LD2 and the bank portion PT from external moisture, humidity, and the like. The first capping layer CP1 may include at least one material such as silicon nitride (SiNₓ), silicon oxide (SiOₓ), silicon oxynitride (SiOₓN_{y}), and aluminum oxide (AlOₓ). However, a material of the first capping layer CP1 is not limited thereto.

The first capping layer CP1 may be disposed on the bank portion PT and may extend along a surface shape of the bank portion PT. For example, the surface area of the first capping layer CP1 may increase due to the bank portion PT. As the surface area of the first capping layer CP1 increases, a penetration distance of external moisture and humidity through the first capping layer CP1 may increase.

On the first capping layer CP1, the first encapsulation layer ENC1 covering the second light emitting element LD2 may be disposed. The first encapsulation layer ENC1 may overlap the second light emitting element LD2 and may be spaced apart from the first light emitting element LD1. The first encapsulation layer ENC1 may protect components disposed under the first encapsulation layer ENC1 and may provide a substantially flat upper surface.

The first encapsulation layer ENC1 may include an organic insulating layer including an organic material. The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

In embodiments, the first encapsulation layer ENC1 may overlap the second light emitting element LD2 and may be disposed inside the bank portion PT. For example, the bank portion PT may be positioned at the interface between the first encapsulation layer ENC1 and the second encapsulation layer ENC2 in a plan view. The first encapsulation layer ENC1 and the second encapsulation layer ENC2 may be separated from each other in a plan view by the bank portion PT.

The second capping layer CP2 may be disposed on the first encapsulation layer ENC1 and the first capping layer CP1. The second capping layer CP2 may define an opening overlapping the first pixel opening POP1. The first light emitting element LD1 may be disposed in the opening. The second capping layer CP2 may protect components under the second capping layer CP2, such as the first encapsulation layer ENC1, from external moisture, humidity, and the like. The second capping layer CP2 may include at least one material such as silicon nitride (SiNₓ), silicon oxide (SiOₓ), silicon oxynitride (SiOₓN_{y}), and aluminum oxide (AlOₓ). However, a material of the second capping layer CP2 is not limited thereto.

The second capping layer CP2 may extend along a surface shape of the first capping layer CP1 on the bank portion PT. For example, similarly to the first capping layer CP1, the surface area of the second capping layer CP2 may increase due to the bank portion PT. As the surface area of the second capping layer CP2 increases, a penetration distance of external moisture and oxygen through the second capping layer CP2 may increase.

In embodiments, the first capping layer CP1 and the second capping layer CP2 may contact each other on the bank portion PT and extend along a surface of the bank portion PT. Since the bank portion PT has a shape protruding from the substrate SUB in the third direction DR3, the contact area between the first capping layer CP1 and the second capping layer CP2 on the bank portion PT may increase due to the bank portion PT. For example, the contact area between the first capping layer CP1 and the second capping layer CP2 in a corresponding area PA may be greater than a planar area of the area PA where the bank portion PT may be disposed.

Because a number of layers preventing external moisture and oxygen may be two layers in the area where the first capping layer CP1 and the second capping layer CP2 contact, it may be difficult for external moisture and oxygen to penetrate into the display panel. As the contact area between the first capping layer CP1 and the second capping layer CP2 increases, a penetration distance of external moisture and oxygen into the display panel may increase. As the penetration distance of external moisture and oxygen increases, a possibility that external moisture and oxygen may penetrate into the second light emitting element LD2 in the display panel may decrease. Accordingly, the first capping layer CP1 and the second capping layer CP2 may readily protect lower components (for example, the second light emitting element LD2) from external moisture, oxygen, and the like, and may prevent damage to components (for example, the second light emitting element LD2) due to external moisture and oxygen penetration.

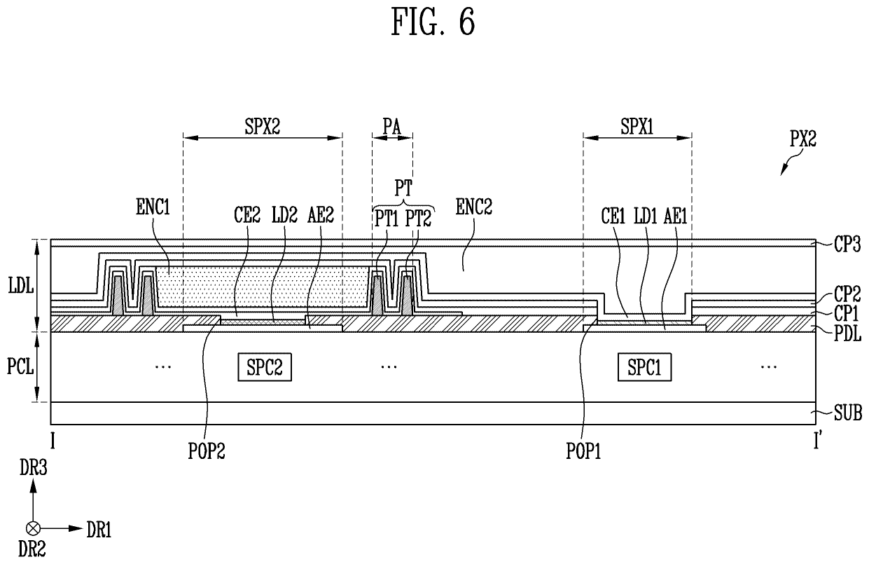

FIG. 6 is a schematic cross-sectional view according to an embodiment of FIG. 5.

Compared to the pixel PX1 described above, a type of the first light emitting element LD1 of a pixel PX2 according to the embodiment may be different from a type of the first light emitting element LD1 of the pixel PX1. Specifically, in pixel PX2 of FIG. 6, the first light emitting element LD1 may be a quantum dot light emitting element as opposed to the inorganic light emitting element for first light emitting element LD1 of FIG. 5. Therefore, a content that may overlap the content described above is briefly described or is not repeated.

Referring to FIGS. 4 and 6, the first light emitting element LD1 may be a quantum dot light emitting element including a quantum dot which is an inorganic material. The second and third light emitting elements LD2 and LD3 may be organic light emitting elements including an organic material. For example, the pixel PX2 may configure the first light emitting element LD1 generating the light of the blue color as a quantum dot light emitting diode and configure the second light emitting element LD2 generating the light of the red color and the third light emitting element LD3 generating the light of the green color as organic light emitting elements. Accordingly, the pixel PX2 may include both of the quantum dot light emitting element and the organic light emitting element so that emission efficiency may be maximized for each color.

The first anode electrode AE1 may be disposed on the pixel circuit layer PCL. The pixel defining layer PDL may be disposed on the first anode electrode AE1. The pixel defining layer PDL may have the first pixel opening POP1 exposing a portion of the first anode electrode AE1. The first light emitting element LD1 may be disposed in the first pixel opening POP1 of the pixel defining layer PDL.

On the first anode electrode AE1, the first light emitting element LD1 may be disposed in the first pixel opening POP1 of the pixel defining layer PDL. The first light emitting element LD1 may emit the light of the blue color and may include a quantum dot. For example, the first light emitting element LD1 may be a quantum dot light emitting element. The first light emitting element LD1 may include a resin portion and a quantum dot, which is a scatterer and a wavelength conversion particle dispersed in the resin portion.

The first cathode electrode CE1 may be disposed on the first light emitting element LD1 and the second capping layer CP2. The first cathode electrode CE1 may be disposed on the first light emitting element LD1 through the first pixel opening POP1 and may overlap the first light emitting element LD1. The first cathode electrode CE1 may continuously extend on the display area DA of the display panel DP of FIG. 3 across the plurality of pixels PX2.

The first sub-pixel circuit SPC1, the first light emitting element LD1, the first anode electrode AE1, and the first cathode electrode CE1 may configure the first sub-pixel SPX1.

The second encapsulation layer ENC2 may be disposed on the first cathode electrode CE1. At this time, the second encapsulation layer ENC2 may overlap not only the first sub-pixel SPX1 but also the second sub-pixel SPX2. For example, the second encapsulation layer ENC2 may extend from an area where the first sub-pixel SPX1 is disposed to an area where the second sub-pixel SPX2 is disposed. The second encapsulation layer ENC2 may protect components disposed under the second encapsulation layer ENC2 and provide a substantially flat upper surface.

A third capping layer CP3 may be disposed on the second encapsulation layer ENC2. The third capping layer CP3 may protect components under the third capping layer CP3 such as the second encapsulation layer ENC2 from external moisture, humidity, and the like. The third capping layer CP3 may include at least one of a material such as silicon nitride (SiNₓ), silicon oxide (SiOₓ), silicon oxynitride (SiOₓN_{y}), and aluminum oxide (AlOₓ). However, a material of the third capping layer CP3 is not limited thereto.

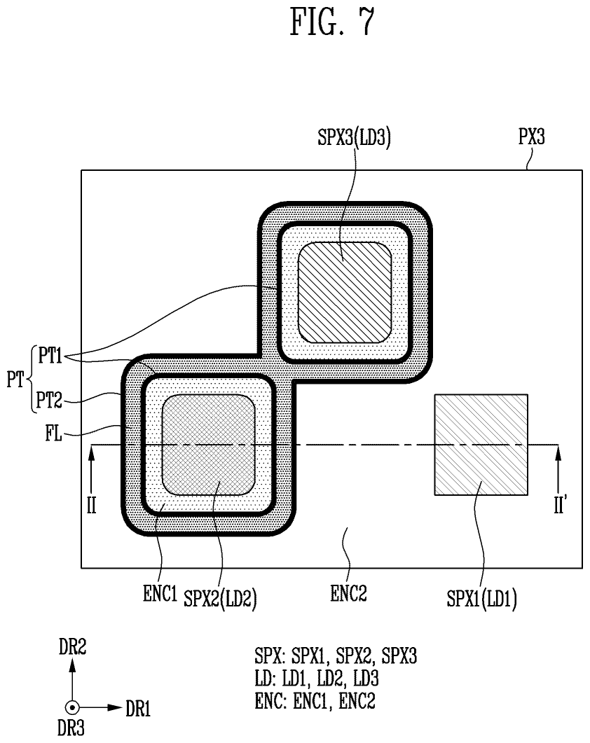

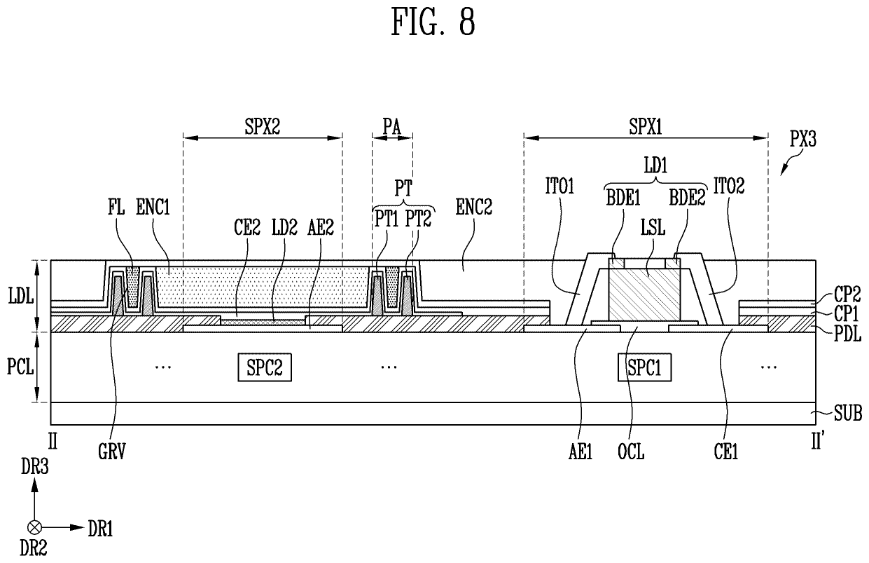

FIG. 7 is a schematic plan view according to an embodiment of FIG. 4. FIG. 8 is a schematic cross-sectional view taken along line II-II′ of FIG. 7.

Compared to the pixel PX1 of FIG. 4 described above, a pixel PX3 according to the embodiment is different from the pixel PX1 of FIG. 4 described above in that the pixel PX3 may include a filling layer FL. Therefore, a content that may overlap the content described above is briefly described or is not repeated.

Referring to FIGS. 7 and 8, the pixel PX3 may further include the filling layer FL disposed on the first capping layer CP1 and disposed under the second capping layer CP2.

The filling layer FL may fill a groove GRV between the first bank PT1 and the second bank PT2. Since the first bank PT1 and the second bank PT2 protrude from the pixel defining layer PDL in the third direction DR3 and are not planarized, the groove GRV may be defined between the first bank PT1 and the second bank PT2 A. For example, the filling layer FL may be disposed in the groove GRV defined by the first bank PT1 and the second bank PT2 on the first capping layer CP1.

The filling layer FL may be formed of a material that absorbs moisture. In embodiments, the filling layer FL may include at least one material selected from an inorganic oxide and a complex compound. For example, the filling layer FL may be formed of only at least one material selected from the inorganic oxide and the complex compound. The inorganic oxide may include, for example, at least one of various oxides such as calcium oxide (CaO), magnesium oxide (MgO), and barium oxide (BaO). The complex compound may include, for example, at least one of various oxides such as calcium chloride (CaCl₂), magnesium chloride (MgCl₂), and nickel chloride (NiCl₂). In other embodiments, the filling layer FL may be configured as a state in which at least one material selected from an inorganic oxide and a complex compound is mixed inside a synthetic resin. The synthetic resin may include, for example, at least one of various polymers such as epoxy, urethane, butadiene, and polyester acrylate. In still other embodiments, the filling layer FL may include a metal that reacts with moisture and develops color. For example, the filling layer FL may include a metal or a metal compound including a metal element such as cobalt (Co), copper (Cu), and iron (Fe), which reacts with water and develops color.

In embodiments, as the filling layer FL may be further disposed between the first capping layer CP1 and the second capping layer CP2, the filling layer FL may additionally absorb penetrated external moisture between the first capping layer CP1 and the second capping layer CP2. Accordingly, the pixel PX3 may be resistant to damage due to moisture penetration.

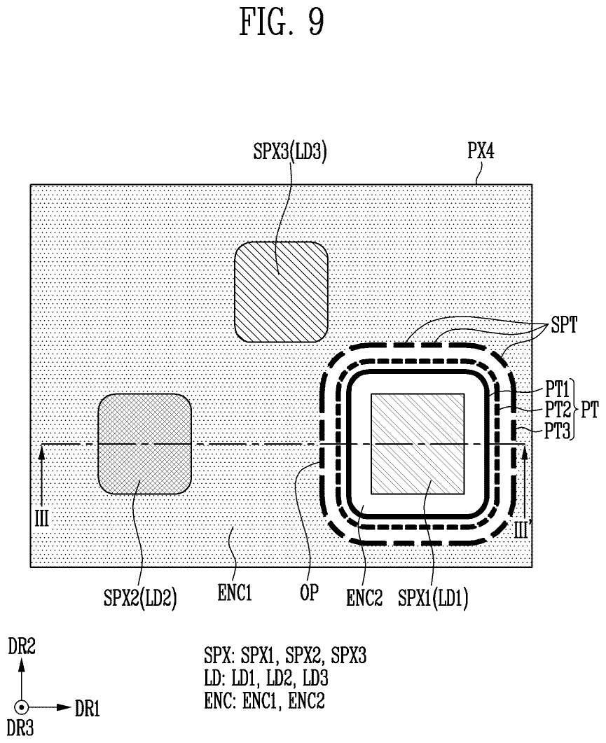

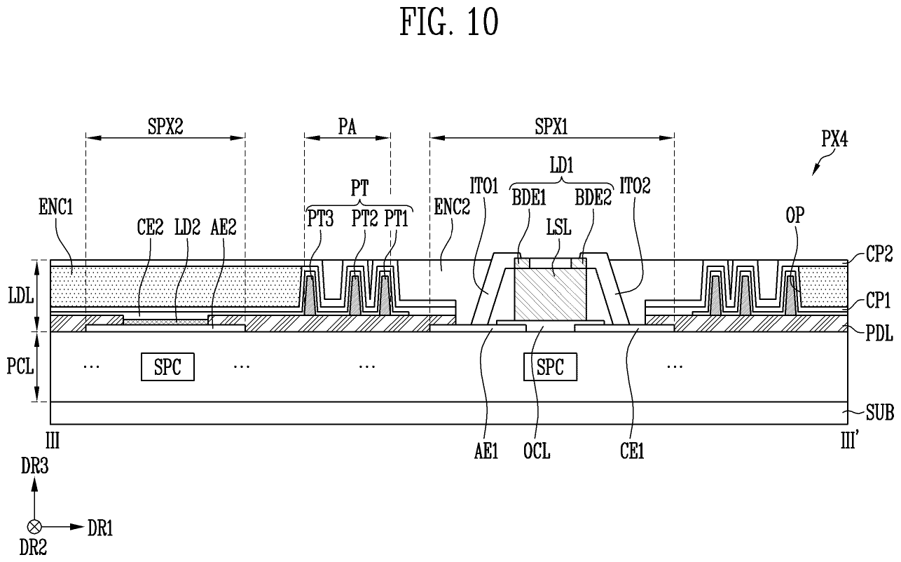

FIG. 9 is a schematic plan view according to an embodiment of FIG. 4. FIG. 10 is a cross-sectional view taken along line III-III′ of FIG. 9.

Compared to the pixel PX1 of FIG. 4 described above, a pixel PX4 according to the embodiment is different from the pixel PX1 of FIG. 4 described above in a position of the bank portion PT, a shape of the bank portion PT, and a disposition of the encapsulation layer ENC due to the position of the bank portion PT. Therefore, a content that may overlap the content described above is briefly described or is not repeated.

Referring to FIGS. 9 and 10, the pixel PX4 may further include the bank portion PT disposed between the first light emitting element LD1 and the second and third light emitting elements LD2 and LD3. For example, the bank portion PT may surround the first light emitting element LD1. Therefore, the first light emitting element LD1 and the second and third light emitting elements LD2 and LD3 may be isolated from each other based on the bank portion PT.

The bank portion PT may include a first bank PT1, a second bank PT2 disposed outside the first bank PT1, and a third bank (or third partition wall) PT3 disposed outside the second bank PT2. The first bank PT1 may have a continuous shape. Each of the second bank PT2 and the third partition PT3 may include two or more sub banks SPT. Two or more sub banks SPT may be spaced apart from each other. For example, each of the second bank PT2 and the third partition PT3 may not have a continuous shape and may have a broken portion in the middle. At this time, a separation distance between the sub banks SPT may be substantially the same, and lengths of the respective sub banks SPT may also be substantially the same. However, embodiments are not limited thereto, and the separation distance between the sub banks SPT may be different from each other, and the lengths of the respective sub banks SPT may also be different from each other.

A separation distance between the first bank PT1 and the second bank PT2 may be different from a separation distance between the second bank PT2 and the third bank PT3. For example, the separation distance between the first bank PT1 and the second bank PT2 may be less than the separation distance between the second bank PT2 and the third bank PT3. However, the separation distance between the first bank PT1 and the second bank PT2 and the separation distance between the second bank PT2 and the third bank PT3 are not limited thereto.

The pixel PX4 may include the encapsulation layer ENC that covers the plurality of light emitting elements LD. The encapsulation layer ENC may include the first encapsulation layer ENC1 covering the second and third light emitting elements LD2 and LD3 and the second encapsulation layer ENC2 covering the first light emitting element LD1. In embodiments, the first encapsulation layer ENC1 may define an opening OP overlapping the first light emitting element LD1. The bank portion PT may be disposed around the opening OP. For example, the bank portion PT may be disposed on a side surface of the opening OP and may be positioned at the interface between the first encapsulation layer ENC1 and the second encapsulation layer ENC2 in a plan view.

In embodiments, the bank portion PT may be disposed between the first light emitting element LD1 and the second light emitting element LD2 in a plan view. The bank portion PT may be positioned at the interface between the first encapsulation layer ENC1 and the second encapsulation layer ENC2 in a plan view. Since the bank portion PT has a shape protruding from the substrate SUB and the first capping layer CP1 and the second capping layer CP2 extend on the bank portion PT along a surface shape of the bank portion PT, the contact area between the first capping layer CP1 and the second capping layer CP2 may increase. Accordingly, a penetration distance of external moisture and oxygen into the display panel may increase. Therefore, damage to the second and third light emitting elements LD2, LD3 due to penetration of external moisture and oxygen may be prevented.

Since the bank portion PT may be partially removed, lines disposed under a removed portion may smoothly transmit an electrical signal without being disturbed by an upper structure.

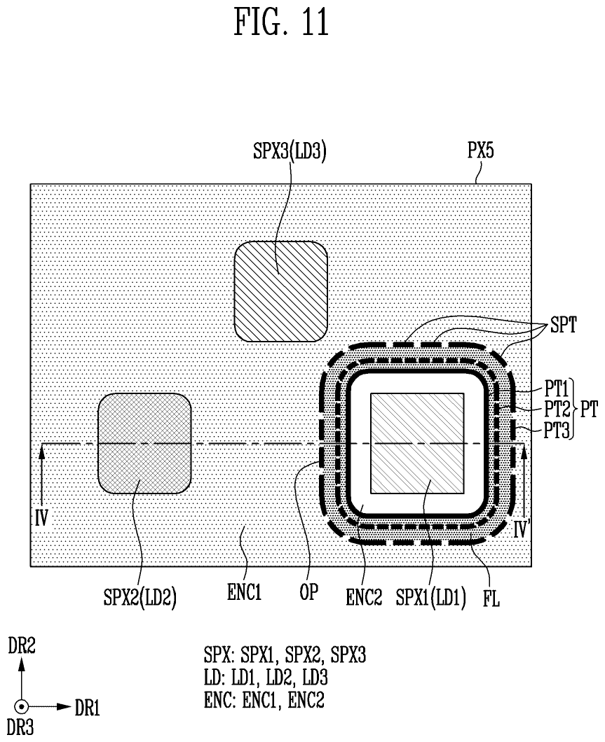

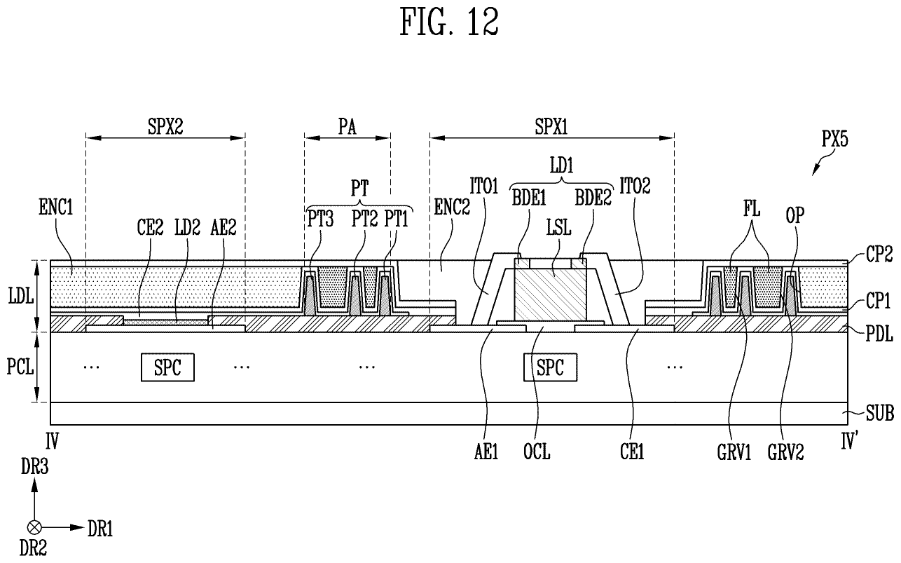

FIG. 11 is a schematic plan view according to an embodiment of FIG. 9. FIG. 12 is a schematic cross-sectional view taken along line IV-IV′ of FIG. 11.

Compared to the pixel PX4 of FIG. 9 described above, a pixel PX5 according to the embodiment is different from the pixel PX4 of FIG. 9 described above in that the pixel PX5 may further include the filling layer FL. Therefore, a content that may overlap the content described above is briefly described or is not repeated.

Referring to FIGS. 11 and 12, the pixel PX5 may further include the filling layer FL disposed on the first capping layer CP1 and disposed under the second capping layer CP2.

The filling layer FL may fill a first groove GRV1 between the first bank PT1 and the second bank PT2 and a second groove GRV2 between the second bank PT2 and the third bank PT3. Since the first bank PT1 and the second bank PT2 protrude from the pixel defining layer PDL in the third direction DR3 and are not planarized, the first groove GRV1 may be defined between the first bank PT1 and the second bank PT2. Similarly, since the second bank PT2 and the third bank PT3 protrude from the pixel defining layer PDL in the third direction DR3 and are not planarized, the second groove GRV2 may be defined between the second bank PT2 and the third bank PT3. In case that the separation distance between the first bank PT1 and the second bank PT2 and the separation distance between the second bank PT2 and the third partition PT3 may be different from each other, a width of the first groove GRV1 and a width of the second groove GRV2 may also be different from each other.

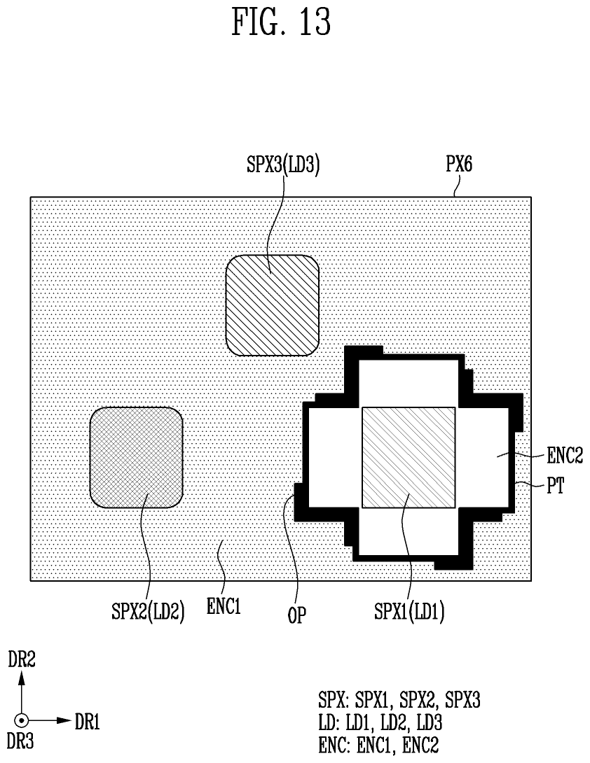

For example, the filling layer FL may be disposed in the first groove GRV1 defined due to the first bank PT1 and the second bank PT2, and the second groove GRV2 defined due to the second bank PT2 and the third bank PT3 on the first capping layer CP1. FIG. 13 is a schematic plan view according to an embodiment of FIG. 9.

Compared to the pixel PX4 of FIG. 9 described above, a pixel PX6 according to the embodiment may be different from the pixel PX4 of FIG. 9 described above in a shape of the bank portion PT surrounding the first light emitting element LD1. Therefore, a content that may overlap the content described above is briefly described or is not repeated.

Referring to FIG. 13, the pixel PX6 may further include the bank portion PT disposed between the first light emitting element LD1 and the second and third light emitting elements LD2 and LD3. For example, the bank portion PT may surround the first light emitting element LD1. Therefore, the first light emitting element LD1 and the second and third light emitting elements LD2 and LD3 may be isolated from each other by the bank portion PT.

The bank portion PT may have various shapes. For example, the bank portion PT may have a cross shape as shown in FIG. 13. Widths of the bank portion PT may be partially different from each other. For example, a width of the bank portion PT may not be formed uniformly, and may be relatively large in a partial area and may be relatively small in a remaining area. However, embodiments according to the disclosure are not limited thereto.

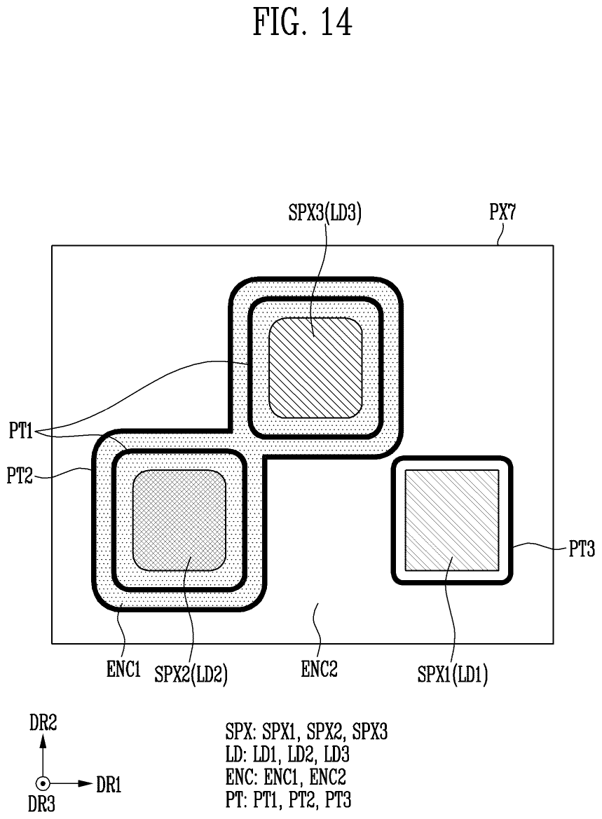

FIG. 14 is a schematic plan view according to an embodiment of FIG. 4.

Compared to the pixel PX1 of FIG. 4 described above, a pixel PX7 according to the embodiment is different from the pixel PX1 of FIG. 4 described above in that the pixel PX7 may include a third bank PT3 surrounding the first light emitting element LD1. Therefore, a content that may overlap the content described above is briefly described or is not repeated.

Referring to FIG. 14, the pixel PX7 may further include the bank portion PT disposed between the first light emitting element LD1 and the second and third light emitting elements LD2 and LD3. For example, the bank portion PT may surround each of the first light emitting element LD1 and the second and third light emitting elements LD2 and LD3. Accordingly, the first light emitting element LD1 and the second and third light emitting elements LD2 and LD3 may be isolated from each other based on the bank portion PT.

The bank portion PT may include a first bank PT1, a second bank PT2 disposed outside the first bank PT1, and a third bank PT3 disposed outside the second bank PT2. Each of the first bank PT1, the second bank PT2, and the third partition PT3 may have a continuous shape. For example, each of the first to third banks PT1, PT2, and PT3 may surround at least one of the first to third light emitting elements LD1, LD2, and LD3 without a broken portion. However, the disclosure is not limited thereto, and in other embodiments, a broken portion may exist in one of the first to third banks PT1, PT2, and PT3.

For example, the first bank PT1 may surround each of the second and third light emitting elements LD2 and LD3, the second bank PT2 may surround the second and third light emitting elements LD2 and LD3, and the third bank PT3 may extend while entirely surrounding the first light emitting element LD1. For example, the first to third light emitting elements LD1, LD2, and LD3 may be surrounded by at least one of the first to third banks PT1, PT2, and PT3.

The pixel PX7 may include the encapsulation layer ENC covering the plurality of light emitting elements LD. The encapsulation layer ENC may include the first encapsulation layer ENC1 covering the second and third light emitting elements LD2 and LD3 and the second encapsulation layer ENC2 covering the first light emitting element LD1.

In embodiments, the bank portion PT may surround the first encapsulation layer ENC1 in a plan view. For example, the first and second banks PT1 and PT2 may surround the second and third light emitting elements LD2 and LD3 in a plan view, and the first encapsulation layer ENC1 may be positioned inside the first and second banks PT1 and PT2 and may overlap the second and third light emitting elements LD2 and LD3. The second encapsulation layer ENC2 may entirely cover a portion where the first encapsulation layer ENC1 may not be disposed, and may overlap the third partition PT3.

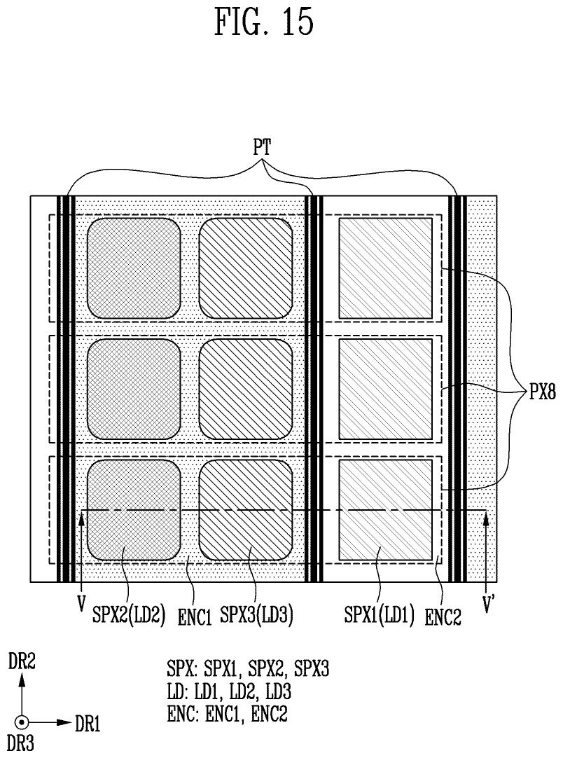

FIG. 15 is a schematic plan view illustrating an embodiment of one of the plurality of pixels of FIG. 3. FIG. 16 is a schematic cross-sectional view taken along line V-V′ of FIG. 15.

Compared to the pixel PX1 of FIG. 4 described above, a pixel PX8 according to the embodiment is different from the pixel PX1 of FIG. 4 described above in an arrangement of the sub-pixels SPX and a disposition of the bank portion PT. Therefore, a content that may overlap the content described above is briefly described or is not repeated.

Referring to FIGS. 15 and 16, multiple pixels PX8 may be arranged in the first direction DR1 and the second direction DR2. Each of the plurality of pixels PX8 may include the first to third sub-pixels SPX1, SPX2, and SPX3. The first to third sub-pixels SPX1, SPX2, and SPX3 may be arranged in the first direction DR1. For example, the second sub-pixel SPX2, the third sub-pixel SPX3, and the first sub-pixel SPX1 may be arranged in the first direction DR1. However, an arrangement of the pixel PX8 is not limited thereto and may variously change according to embodiments.

In embodiments, the pixel PX8 may further include the bank portion PT disposed between the first light emitting element LD1 and the second and third light emitting elements LD2 and LD3. For example, the bank portion PT may be disposed between the third light emitting element LD3 and the first light emitting element LD1 and may extend in the second direction DR2. The bank portion PT may be disposed between the first light emitting element LD1 and the second light emitting element LD2, and may similarly extend in the second direction DR2. Therefore, the first light emitting element LD1 and the second and third light emitting elements LD2 and LD3 may be isolated from each other by the bank portion PT.

The bank portion PT may include one or more banks. In this embodiment, each of the banks may have a continuous shape. For example, since each of the banks does not have a broken portion, each of the banks may isolate the third light emitting element LD3 from the first light emitting element LD1 and may isolate the first light emitting element LD1 from the second light emitting element LD2. However, the disclosure is not limited thereto, and in other embodiments, a broken portion may exist in one of the banks.

The pixel PX8 may include the encapsulation layer ENC covering the plurality of light emitting elements LD. The encapsulation layer ENC may include the first encapsulation layer ENC1 covering the second and third light emitting elements LD2 and LD3 and the second encapsulation layer ENC2 covering the first light emitting element LD1. In embodiments, the bank portion PT may surround the first encapsulation layer ENC1 in a plan view. For example, the bank portion PT may be disposed between the third light emitting element LD3 and the first light emitting element LD1 and between the first light emitting element LD1 and the second light emitting element LD2 in a plan view, and the first encapsulation layer ENC1 may be positioned inside the bank portion PT and may overlap the second and third light emitting elements LD2 and LD3.

In embodiments, the first encapsulation layer ENC1 and the second encapsulation layer ENC2 may be disposed with the bank portion PT between the first encapsulation layer ENC1 and the second encapsulation layer ENC2 in a plan view. For example, the bank portion PT may be positioned at the interface between the first encapsulation layer ENC1 and the second encapsulation layer ENC2, and the first encapsulation layer ENC1 and the second encapsulation layer ENC2 may be divided by the bank portion PT.

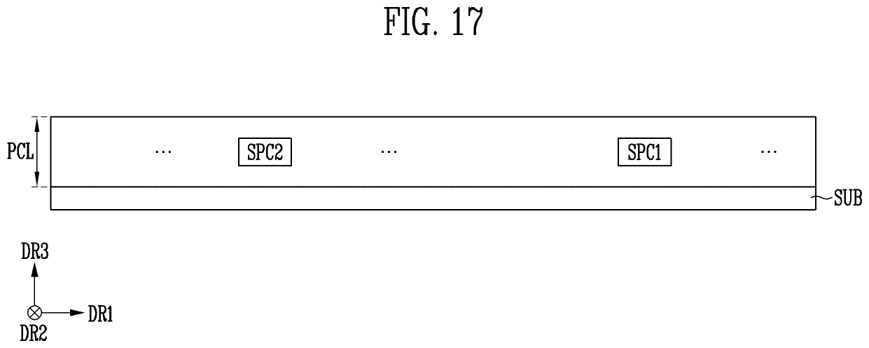

FIGS. 17 to 29 are schematic cross-sectional views illustrating a method of manufacturing a display device according to embodiments. FIGS. 17 to 29 illustrate a method of manufacturing a display device including the pixel PX1 according to the embodiment described above with reference to FIGS. 1 to 5. A content that may overlap the content described above is briefly described or is not repeated.

Referring to FIG. 17, the pixel circuit layer PCL may be formed on the substrate SUB. For example, the sub-pixel circuits SPC1 and SPC2 including transistors and one or more capacitors may be formed on the substrate SUB.

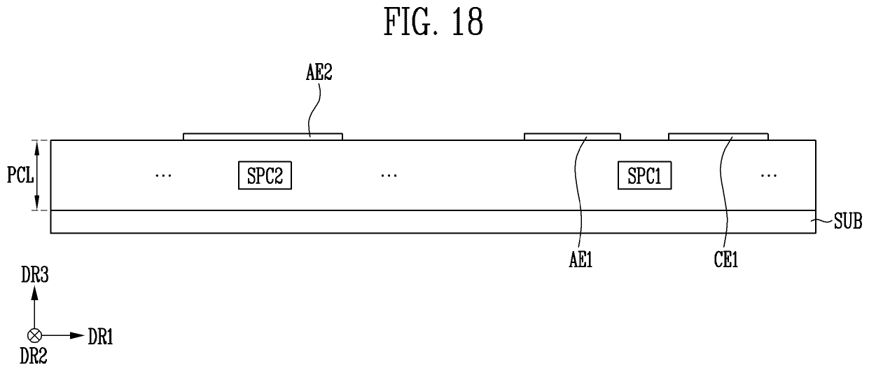

Referring to FIG. 18, the first anode electrode AE1, the first cathode electrode CE1, and the second anode electrode AE2 may be formed on the pixel circuit layer PCL. The first anode electrode AE1 may be formed to be electrically connected to the first sub-pixel circuit SPC1 included in the pixel circuit layer PCL. Similarly, the second anode electrode AE2 may be formed to be electrically connected to the second sub-pixel circuit SPC2 included in the pixel circuit layer PCL. The first cathode electrode CE1 may be formed to be spaced apart from the first anode electrode AE1 in the first direction DR1.

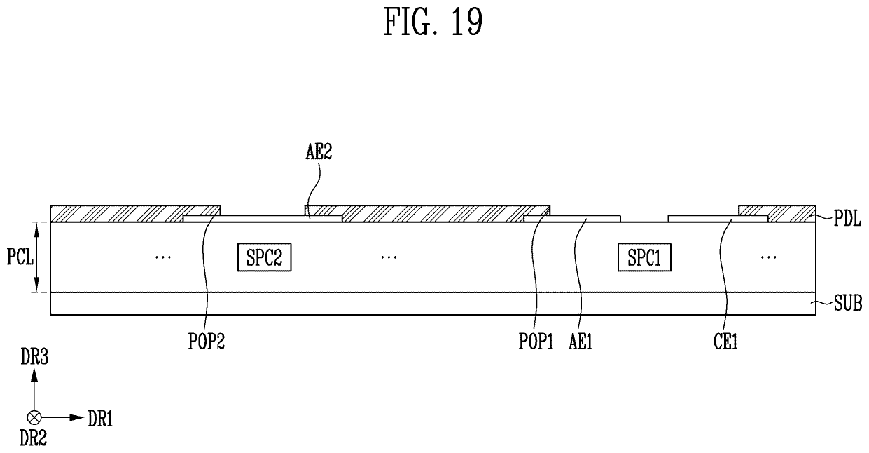

Referring to FIG. 19, the pixel defining layer PDL may be formed on the first anode electrode AE1, the first cathode electrode CE1, and the second anode electrode AE2. The pixel openings POP1 and POP2 exposing portions of the first anode electrode AE1, the first cathode electrode CE1, and the second anode electrode AE2 may be formed in the pixel defining layer PDL.

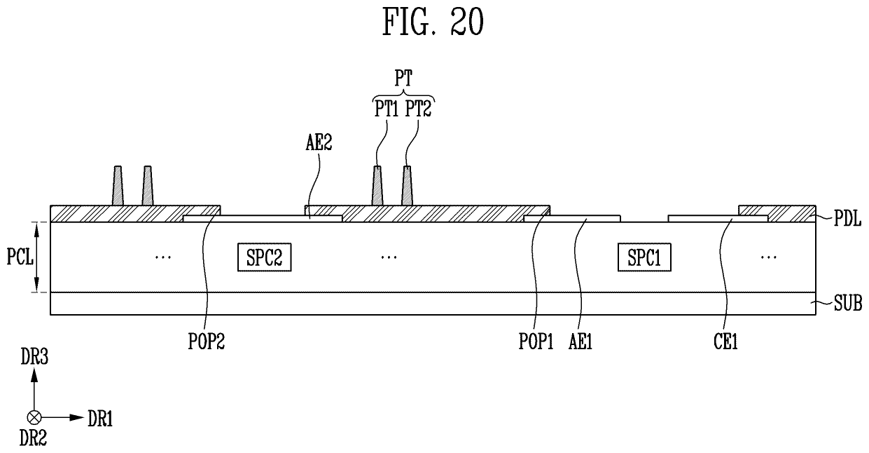

Referring to FIG. 20, the bank portion PT may be formed on the pixel defining layer PDL. The bank portion PT may be formed to protrude from the pixel defining layer PDL in the third direction DR3.

The bank portion PT may be formed between the second pixel opening POP2 and the first pixel opening POP1. For example, the bank portion PT may be formed between the second anode electrode AE2, the first anode electrode AE1, and the first cathode electrode CE1. The bank portion PT may isolate an area where the second anode electrode AE2 may be formed and an area where the first anode electrode AE1 and the first cathode electrode CE1 may be formed. For example, the bank portion PT may be formed to surround the second anode electrode AE2. The bank portion PT may be formed of an inorganic insulating layer including an inorganic material and/or an organic insulating layer including an organic material.

The bank portion PT may include the first bank PT1 and the second bank PT2 formed outside the first bank PT1. Each of the first bank PT1 and the second bank PT2 may be formed in a shape extending while surrounding the second light emitting element LD2 (for example, refer to FIG. 5). However, embodiments are not limited thereto, and one of the first bank PT1 and the second bank PT2 may be formed in a partially removed shape (for example, refer to FIG. 9).

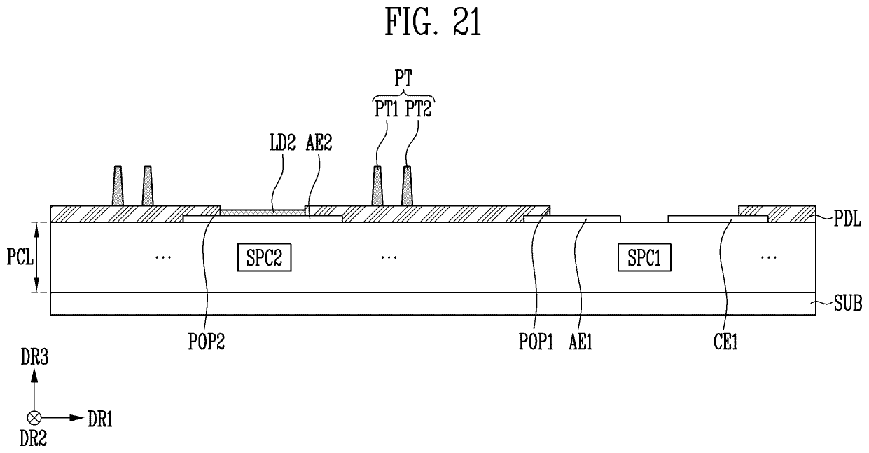

Referring to FIG. 21, the second light emitting element LD2 may be formed in the second pixel opening POP2 on the second anode electrode AE2. The second light emitting element LD2 may be formed of an organic material. For example, the second light emitting element LD2 may be formed as an organic light emitting element.

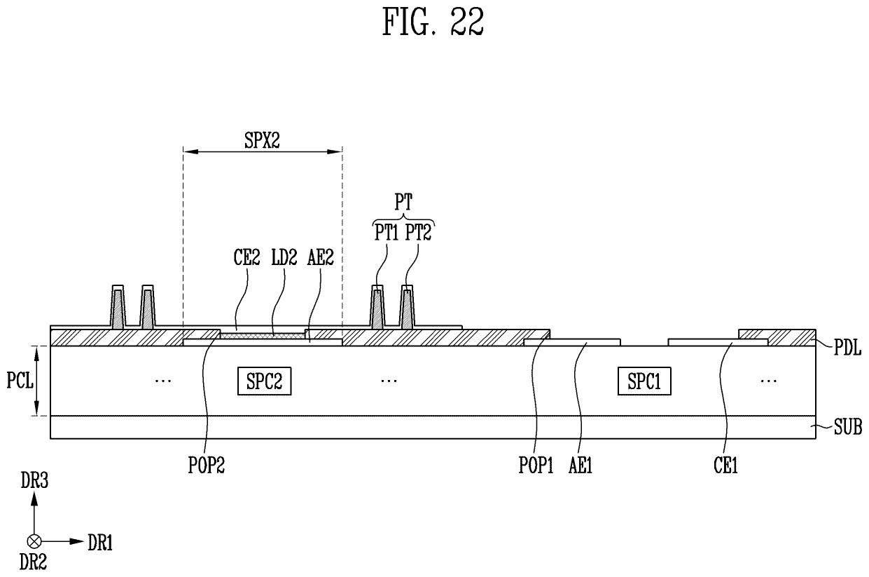

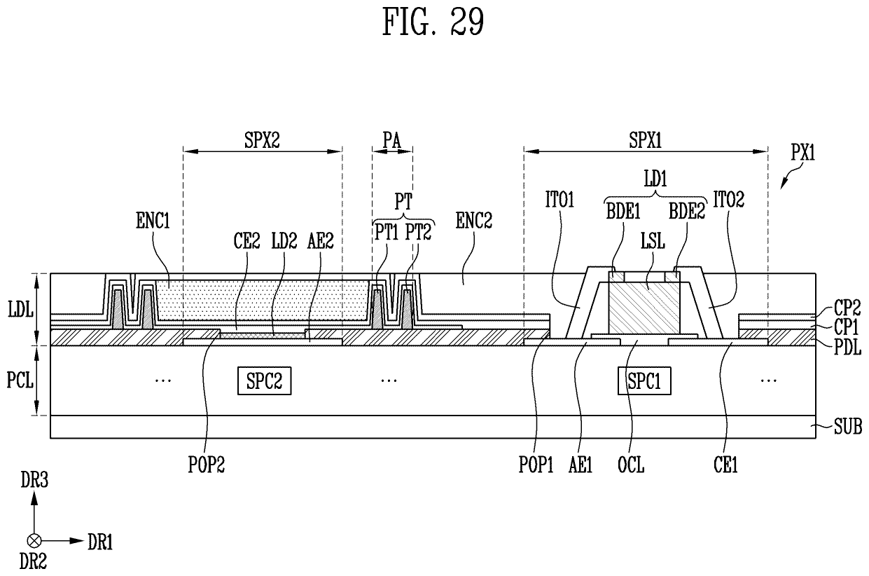

Referring to FIG. 22, the second cathode electrode CE2 may be formed on the pixel defining layer PDL, the bank portion PT, and the second light emitting element LD2. The second cathode electrode CE2 may be formed by entirely forming the second cathode electrode CE2 on the display panel and then removing an electrode disposed on an area (for example, an area overlapping the first pixel opening POP1) where the first sub-pixel (for example, the first sub-pixel SPX1 of FIG. 29) is to be formed.

As the second sub-pixel circuit SPC2, the second anode electrode AE2, the second light emitting element LD2, and the second cathode electrode CE2 may be formed, the second sub-pixel SPX2 including the second anode electrode AE2, the second light emitting element LD2, and the second cathode electrode CE2 may be formed.

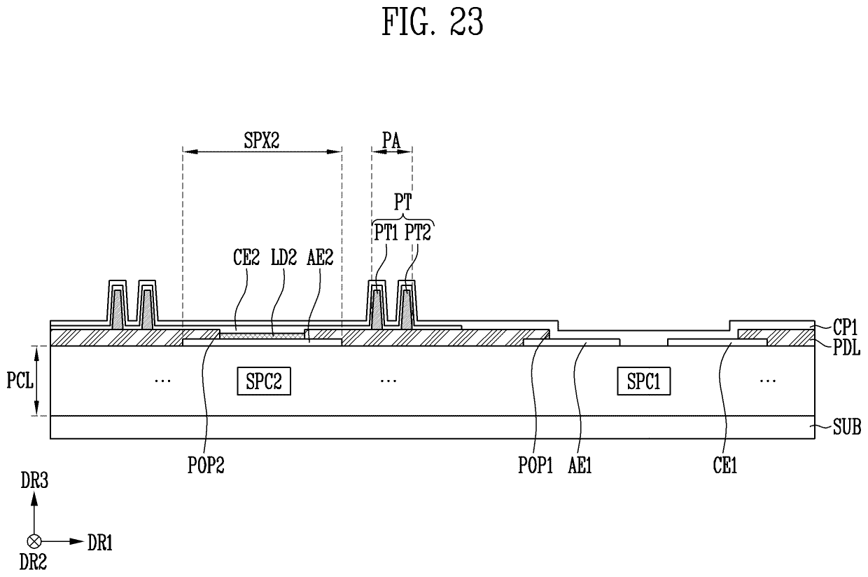

Referring to FIG. 23, the first capping layer CP1 may be formed on the second cathode electrode CE2 and the bank portion PT. The first capping layer CP1 may be entirely formed on the display panel. Therefore, the first capping layer CP1 may be formed to cover a surface of the bank portion PT and extend along a surface shape of the bank portion PT. The first capping layer CP1 may be formed of a metal oxide.

As the first capping layer CP1 extends along the surface shape of the bank portion PT, the area of the first capping layer CP1 in the corresponding area PA may be greater than the planar area of the area PA where the bank portion PT may be disposed.

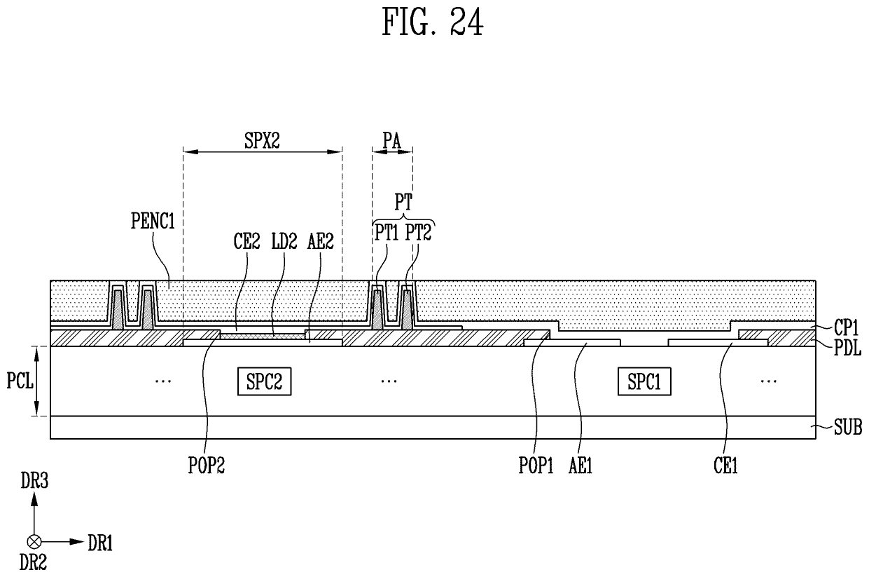

Referring to FIG. 24, a first preliminary encapsulation layer PENC1 may be entirely formed on the first capping layer CP1. The first preliminary encapsulation layer PENC1 may be formed of an organic material.

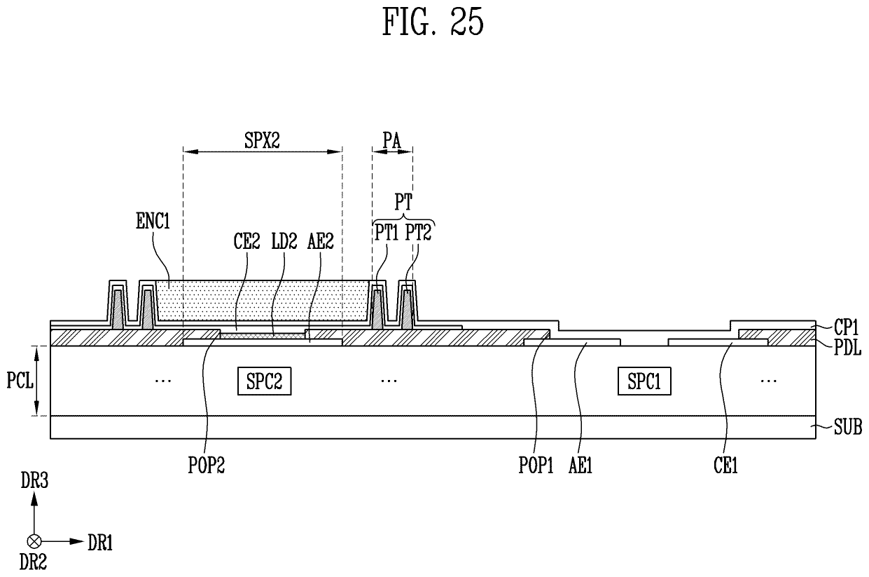

Referring to FIG. 25, after the first preliminary encapsulation layer PENC1 may be formed, the first preliminary encapsulation layer PENC1 of an area spaced apart from the second light emitting element LD2 by the bank portion PT may be removed through an ashing process. For example, the first preliminary encapsulation layer PENCI of an area overlapping the first pixel opening POP1 with respect to the bank portion PT may be removed. Therefore, the first encapsulation layer ENC1 may be formed on an inside of the bank portion PT with respect to the bank portion PT.

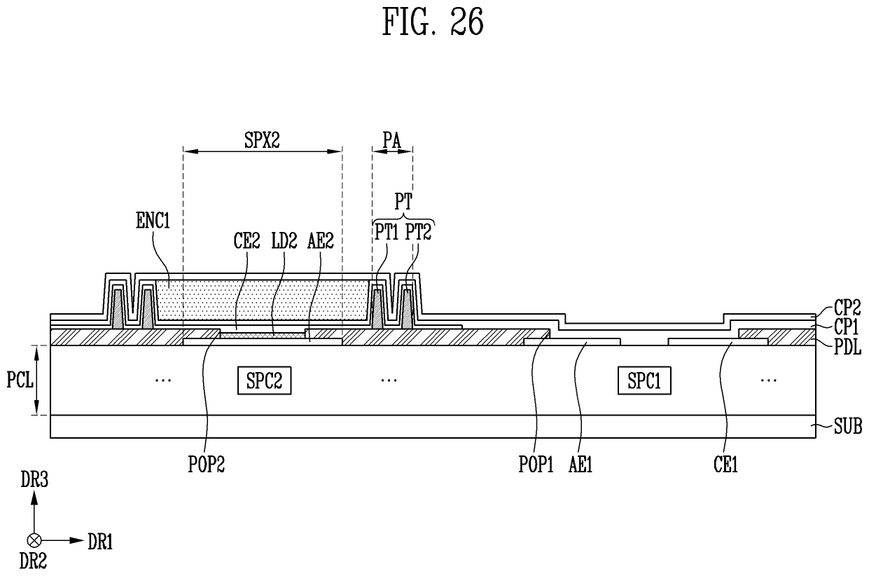

Referring to FIG. 26, the second capping layer CP2 may be formed on the first capping layer CP1 and the first encapsulation layer ENC1. The second capping layer CP2 may cover the first capping layer CP1 on the bank portion PT and may be formed to extend along a surface shape of the first capping layer CP1. The second capping layer CP2 may be formed of a metal oxide.

As the second capping layer CP2 may be formed to extend along the surface shape of the first capping layer CP1 on the bank portion PT, the area of the second capping layer CP2 may be greater than the planar area of the area PA where the bank portion PT may be disposed. Therefore, the contact area between the first capping layer CP1 and the second capping layer CP2 of the corresponding area PA may be greater than the planar area of the area PA where the bank portion PT is disposed. Accordingly, since a penetration distance of external moisture and oxygen through the first capping layer CP1 and the second capping layer CP2 increases, penetration of external moisture and oxygen to the second light emitting element LD2 may be prevented in steps after a step of forming the second light emitting element LD2.

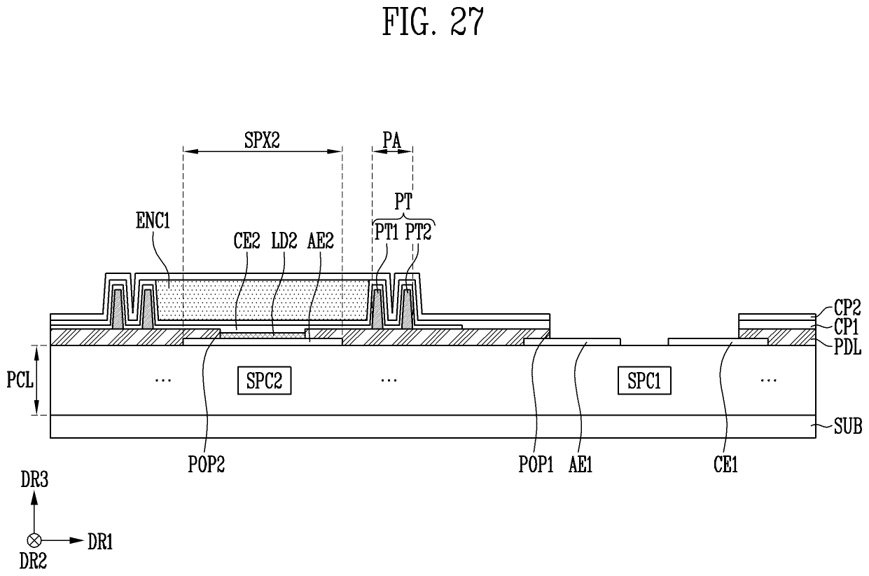

Referring to FIG. 27, the first capping layer CP1 and the second capping layer CP2 of an area overlapping the first pixel opening POP1 may be removed. Therefore, the first anode electrode AE1 and the first cathode electrode CE1 may be exposed.

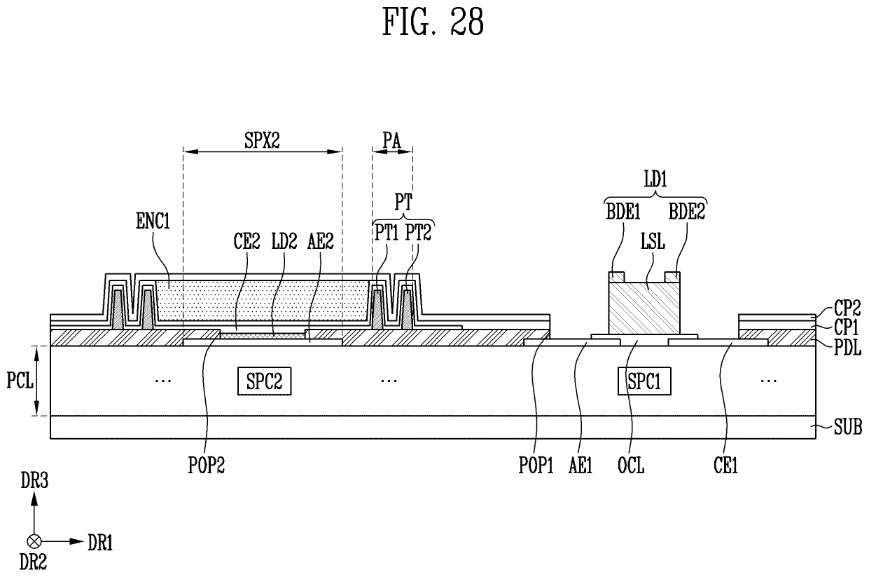

Referring to FIG. 28, the overcoat layer OCL may be formed in the first pixel opening POP1 on the first anode electrode AE1 and the first cathode electrode CE1. The first light emitting element LD1 may be formed in the first pixel opening POP1 on the overcoat layer OCL.

The first light emitting element LD1 may emit the light of the blue color and may be formed of an inorganic material. For example, the first light emitting element LD1 may be an inorganic light emitting element. The first light emitting element LD1 may include the light emitting stack LSL and the first and second bonding electrodes BDE1 and BDE2 disposed on the light emitting stack LSL.

The first light emitting element LD1 and the second light emitting element LD2 may be formed with the bank portion PT between the first light emitting element LD1 and the second light emitting element LD2. For example, the bank portion PT may be formed between the first light emitting element LD1 and the second light emitting element LD2 to isolate the first light emitting element LD1 and the second light emitting element LD2 from each other.

Referring to FIG. 29, the second encapsulation layer ENC2 may be formed on the second capping layer CP2 and the first light emitting element LD1. The second encapsulation layer ENC2 may be formed to overlap the first light emitting element LD1. The second encapsulation layer ENC2 may be positioned in an area overlapping the first light emitting element LD1 with respect to the bank portion PT, and the first encapsulation layer ENC1 may be positioned in an area overlapping the second light emitting element LD2 with respect to the bank portion PT. Therefore, the first encapsulation layer ENC1 and the second encapsulation layer ENC2 may be divided by the bank portion PT.

The first and second transparent electrodes ITO1 and ITO2 may be formed on the second encapsulation layer ENC2. The first transparent electrode ITO1 may be formed to contact the first bonding electrode BDE1 and contact the first anode electrode AE1. The second transparent electrode ITO2 may be formed to contact the second bonding electrode BDE2 and contact the first cathode electrode CE1. The first and second transparent electrodes ITO1 and ITO2 may contact the first anode electrode AE1 and the first cathode electrode CE1 through contact holes formed in the second encapsulation layer ENC2, respectively.

As the first sub-pixel circuit SPC1, the first anode electrode AE1, the first cathode electrode CE1, the first light emitting element LD1, and the first and second transparent electrodes ITO1 and ITO2 are formed, the first sub-pixel SPX1 including the first sub-pixel circuit SPC1, the first anode electrode AE1, the first cathode electrode CE1, the first light emitting element LD1, and the first and second transparent electrodes ITO1 and ITO2 may be formed.

Accordingly, the pixel PX1 including the first sub-pixel SPX1 including an inorganic light emitting element and the second sub-pixel SPX2 including an organic light emitting element may be formed.

In embodiments, after the second sub-pixel SPX2 is formed, in case that the first encapsulation layer ENC1 and the capping layers CP1 and CP2 on the first anode electrode AE1 and the first cathode electrode CE1 with respect to the bank portion PT are removed to form the first sub-pixel SPX1, a side surface of the first encapsulation layer ENC1 may not be exposed and may be covered by the bank portion PT. As the bank portion PT increases the contact area between the first capping layer CP1 and the second capping layer CP2, a penetration distance of external moisture and oxygen may increase. Accordingly, after the second light emitting element LD2 is formed, penetration of external moisture and oxygen into the second light emitting element LD2 through the first and second capping layers CP1 and CP2 and the first encapsulation layer ENC1 and damage to the second sub-pixel SPX2 may be prevented.

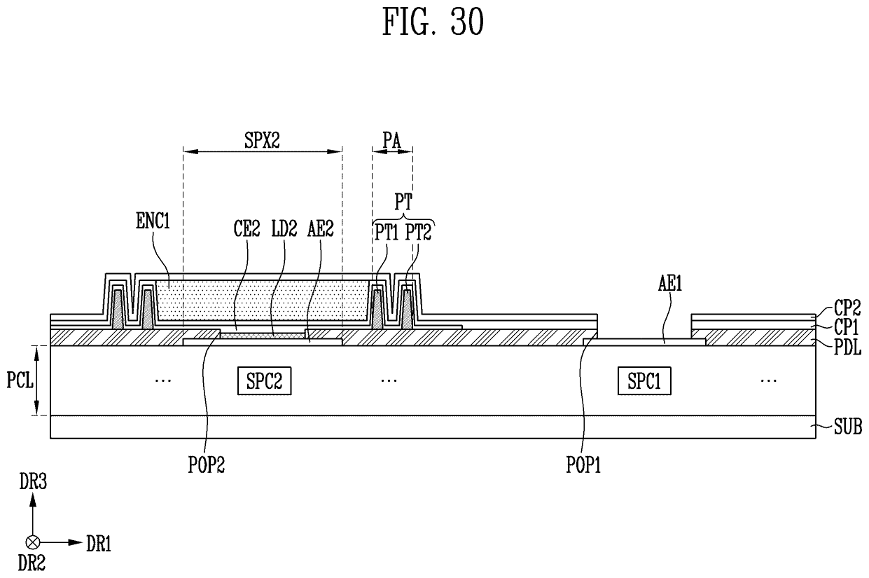

FIGS. 30 to 34 are schematic cross-sectional views according to an embodiment of FIGS. 17 to 29. FIGS. 30 to 34 illustrate a method of manufacturing a display device including the pixel PX2 according to the embodiment described above with reference to FIG. 6.

Compared to the method of manufacturing the pixel PX1 described above, the method of manufacturing the pixel PX2 according to the embodiment is different from the method of manufacturing the pixel PX1 described above in that the types of the first light emitting elements LD1 as an inorganic light emitting element (for example, the first light emitting element LD1 of the pixel PX1 described above) and a quantum dot light emitting element (for example, the first light emitting element LD1 of the pixel PX2 according to the embodiment). Therefore, a content that may overlap the content described above is briefly described or is not repeated.

Referring to FIG. 30, the pixel circuit layer PCL may be formed on the substrate SUB. The first anode electrode AE1 and the second anode electrode AE2 may be formed on the pixel circuit layer PCL. The pixel defining layer PDL may be formed on the first anode electrode AE1 and the second anode electrode AE2. The pixel openings POP1 and POP2 exposing portions of each of the first anode electrode AE1 and the second anode electrode AE2 may be formed in the pixel defining layer PDL.

The second light emitting element LD2 may be formed in the second pixel opening POP2 on the second anode electrode AE2, the bank portion PT may be formed on the pixel defining layer PDL, and the second cathode electrode CE2, the first capping layer CP1, the first encapsulation layer ENC1, and the second capping layer CP2 may be formed on the pixel defining layer PDL and the bank portion PT.

The first capping layer CP1 and the second capping layer CP2 of an area overlapping the first pixel opening POP1 may be removed. Therefore, the first anode electrode AE1 may be exposed.

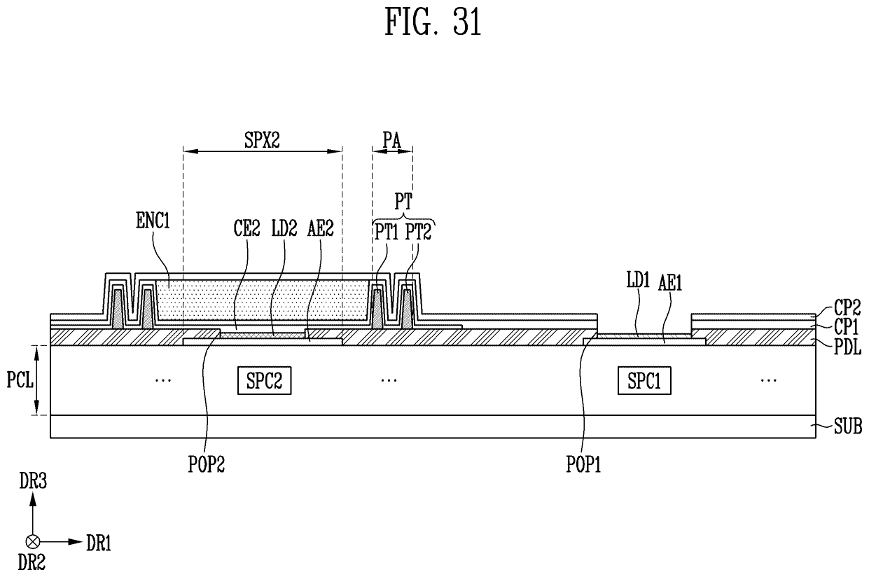

Referring to FIG. 31, the first light emitting element LD1 may be formed on the first pixel opening POP1 on the first anode electrode AE1 and. The first light emitting element LD1 may be formed of a quantum dot which is an inorganic material. For example, the first light emitting element LD1 may be a quantum dot light emitting element.

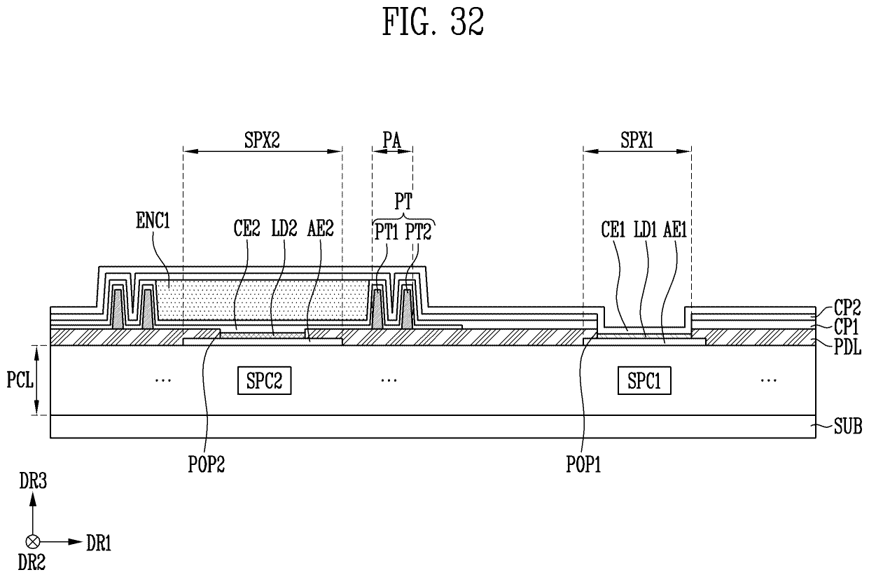

Referring to FIG. 32, the first cathode electrode CE1 may be formed on the first light emitting element LD1 and the second capping layer CP2. The first cathode electrode CE1 may be formed on the first light emitting element LD1 through the first pixel opening POP1 and may overlap the first light emitting element LD1. The first cathode electrode CE1 may be continuously formed on the display panel across the plurality of pixels PX2.

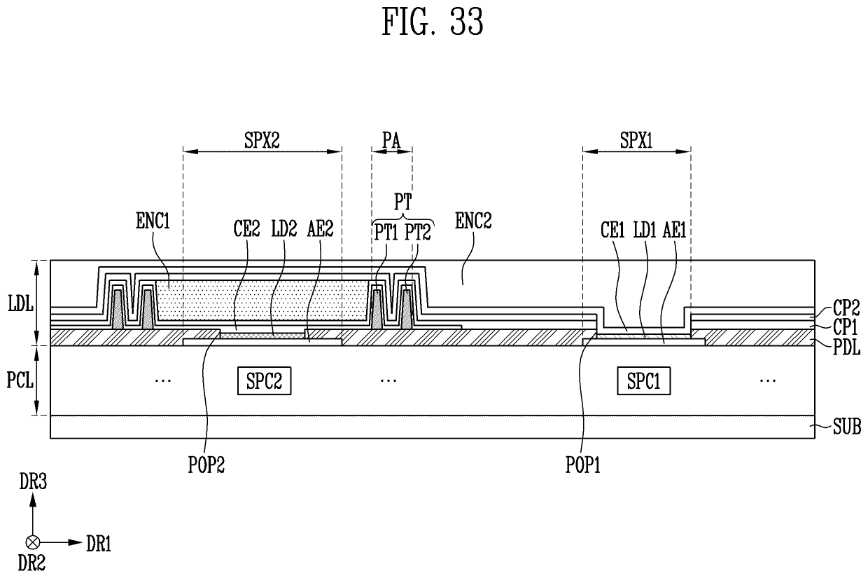

Referring to FIG. 33, the second encapsulation layer ENC2 may be formed on the first cathode electrode CE1. The second encapsulation layer ENC2 may be continuously formed on the display panel. For example, the second encapsulation layer ENC2 may be formed to overlap not only the first sub-pixel SPX1 but also the second sub-pixel SPX2.

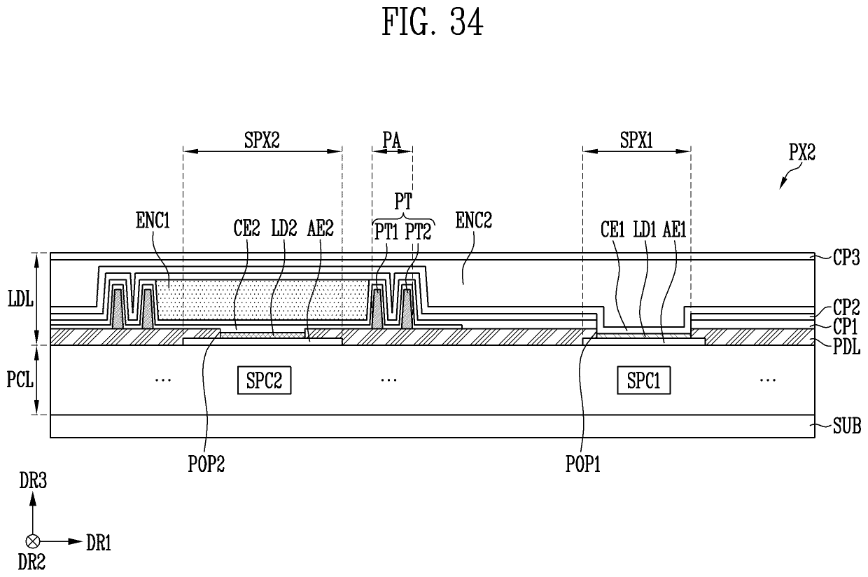

Referring to FIG. 34, a third capping layer CP3 may be formed on the second encapsulation layer ENC2. The third capping layer CP3 may be continuously formed on the display panel. The third capping layer CP3 may be formed of a metal oxide.

Accordingly, the pixel PX2 including the first sub-pixel SPX1 including the quantum dot light emitting element and the second sub-pixel SPX2 including the organic light emitting element may be formed.

The method of manufacturing the pixel PX2 included in the display device according to the embodiment is described under an assumption of a process in which the second sub-pixel SPX2 is formed before the first sub-pixel SPX1, but embodiments according to the disclosure are not limited thereto, and in other embodiments, the first sub-pixel SPX1 may be formed before the second sub-pixel SPX2. Therefore, a structure change according to a process sequence change may exist.

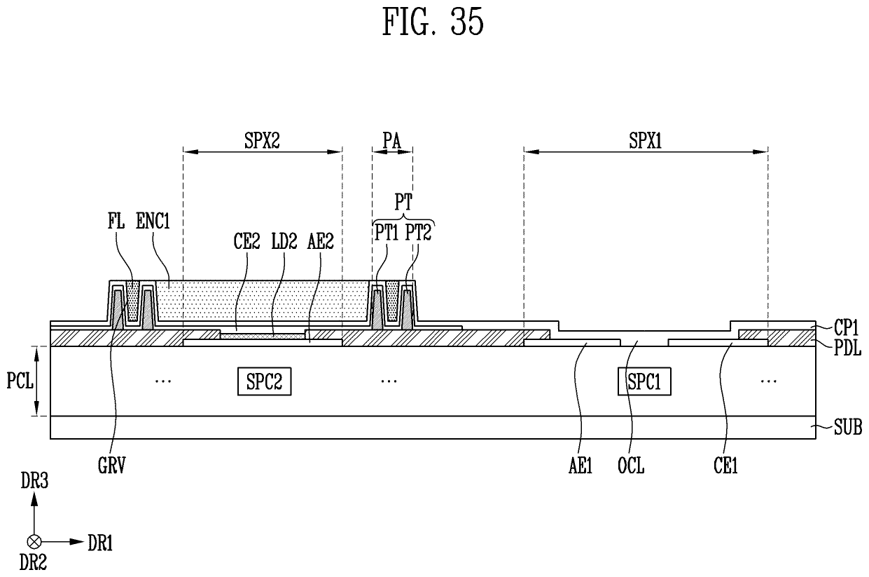

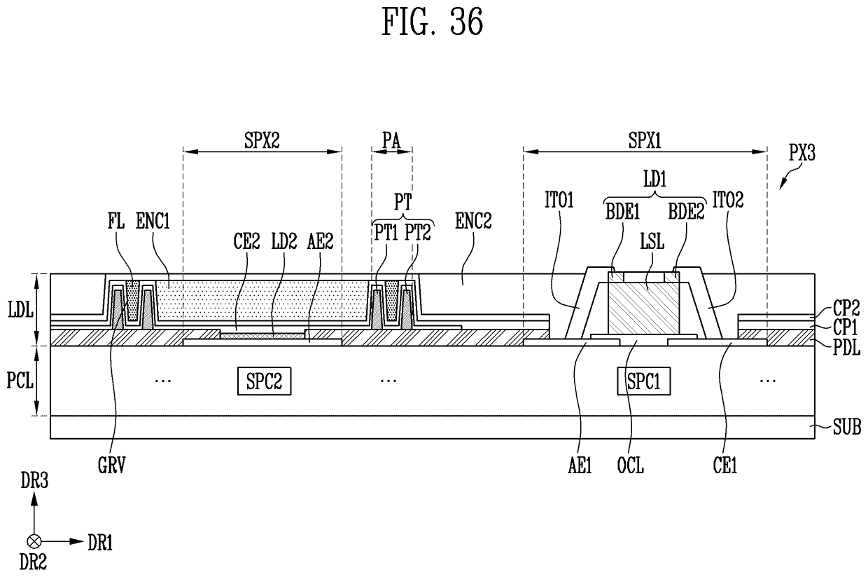

FIGS. 35 and 36 are schematic cross-sectional views according to still an embodiment of FIGS. 17 to 29. FIGS. 35 and 36 illustrate a method of manufacturing a display device including the pixel PX3 according to the embodiment described above with reference to FIGS. 7 and 8. FIG. 35 is a step after a step of FIG. 25 in the method of manufacturing the pixel PX1 described above.

Compared to the method of manufacturing the pixel PX1 described above, the method of manufacturing the pixel PX3 according to the embodiment is different from the method of manufacturing the pixel PX1 described above in that the method of manufacturing the pixel PX3 may include forming the filling layer FL between forming the first capping layer CP1 and forming the second capping layer CP2. Therefore, a content that may overlap the content described above is briefly described or is not repeated.

Referring to FIGS. 35 and 36, the filling layer FL may be formed on the first capping layer CP1. The filling layer FL may be formed in the groove GRV formed between the first bank PT1 and the second bank PT2.

The filling layer FL may be formed of a material that absorbs moisture. In embodiments, the filling layer FL may be formed of at least one material selected from an inorganic oxide and a complex compound. In other embodiments, the filling layer FL may be formed in a state in which at least one material selected from an inorganic oxide and a complex compound is mixed inside a synthetic resin. In still other embodiments, the filling layer FL may be formed of a metal that reacts with moisture and develops color.

Since the filling layer FL may be formed of the material that absorbs moisture, the filling layer FL may additionally prevent moisture and oxygen from penetrating from an outside between the first capping layer CP1 and the second capping layer CP2. Accordingly, penetration of external moisture and oxygen into the second sub-pixel SPX2 and damage to the second sub-pixel SPX2 may be prevented.

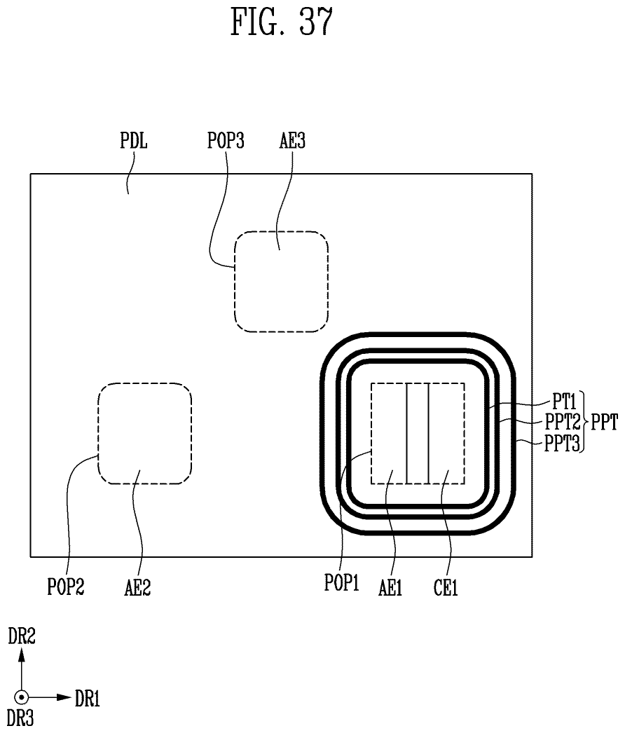

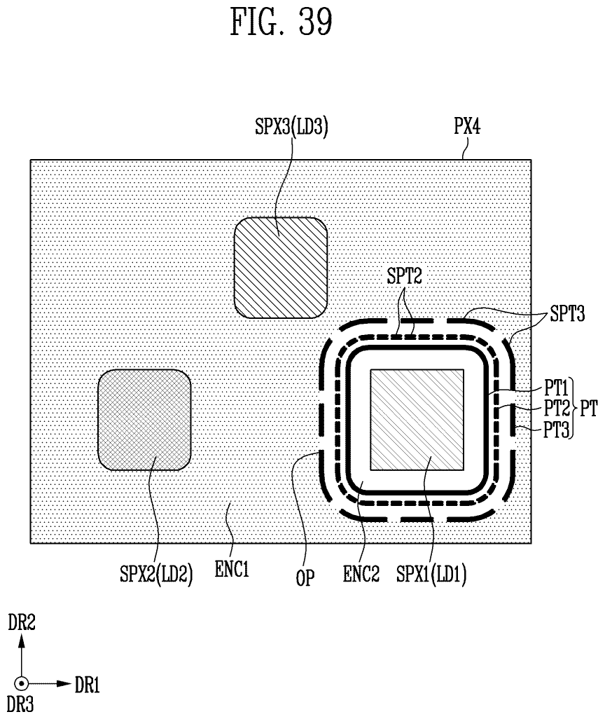

FIGS. 37 to 39 are schematic plan views according to an embodiment of FIGS. 17 to 29. FIGS. 37 and 39 illustrate a method of manufacturing a display device including the pixel PX4 according to the embodiment described above with reference to FIGS. 9 and 10. FIG. 37 is a step corresponding to a step of FIG. 20 in the method of manufacturing the pixel PX1 described above.

Compared to the method of manufacturing the pixel PX1 described above, the method of manufacturing the pixel PX4 according to the embodiment is different from the method of manufacturing the pixel PX1 described above in that the method of manufacturing the pixel PX4 further forms the third bank PT3 and forms the second and third banks PT2 and PT3 by partially removing second and third preliminary banks PPT2 and PPT3 in forming the bank portion PT. Therefore, a content that may overlap the content described above is briefly described or is not repeated.

Referring to FIG. 37, a first pixel opening POP1 exposing the first anode electrode AE1 and the first cathode electrode CE1, a second pixel opening POP2 exposing the second anode electrode AE2, and a third pixel opening POP3 exposing the third anode electrode AE3 may be formed in the pixel defining layer PDL.

A preliminary bank portion PPT may be formed between the first pixel opening POP1 and the second and third pixel openings POP2 and POP3 on the pixel defining layer PDL. The preliminary bank portion PPT may include the first bank PT1 surrounding the first pixel opening POP1, the second preliminary bank PPT2 positioned outside the first bank PT1, and the third preliminary bank PPT3 positioned outside the second preliminary bank PPT2. The first bank PT1, the second preliminary bank PPT2, and the third preliminary bank PPT3 may be formed to have a continuous shape.

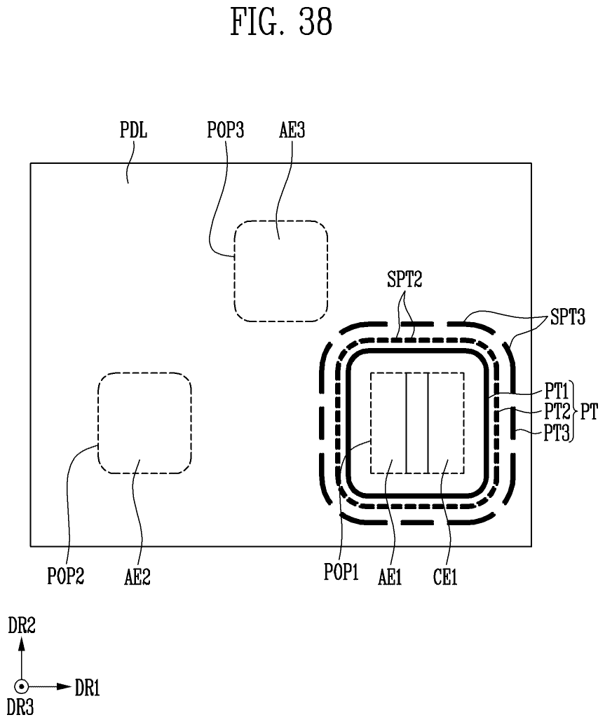

Referring to FIG. 38, each of the second preliminary bank PPT2 and the third preliminary bank PPT3 may be partially removed. For example, the second bank PT2 including second sub banks SPT2 spaced apart from each other may be formed by partially removing the second preliminary bank PPT2. The third bank PT3 including third sub banks SPT3 spaced apart from each other may be formed by partially removing the third preliminary bank PPT3. However, the manufacturing method according to embodiments is not limited thereto. Only one of the second preliminary bank PPT2 and the third preliminary bank PPT3 may be partially removed, and the first bank PT1 other than the second preliminary bank PPT2 and the third preliminary bank PPT3 may be partially removed to form a bank including multiple sub banks.

Therefore, the bank portion PT including the first bank PT1, the second bank PT2, and the third partition PT3 may be formed.

Referring to FIG. 39, after the bank portion PT is formed, the first to third light emitting elements LD1, LD2, and LD3 may be formed, and thus the first to third sub-pixels SPX1, SPX2, and SPX3 may be formed. The first encapsulation layer ENC1 and the second encapsulation layer ENC2 may be formed separately from each other by the bank portion PT.

Therefore, the pixel PX4 including the first light emitting element LD1 and the second and third light emitting elements LD2 and LD3 isolated with respect to the bank portion PT may be formed.

In embodiments, as the bank portion PT may be partially removed, lines disposed under a removed portion may smoothly transmit an electrical signal without being disturbed by an upper structure.

Although the technical idea of the disclosure has been described in detail according to the above-described embodiments, it should be noted that the above-described embodiments are for description and not limitation. Those skilled in the art will understand that various modifications are possible within the scope of the technical idea of the disclosure.

The scope of the disclosure is not limited to the details described in the detailed description of the specification, but should be defined by the claims. It is to be construed that all changes or modifications derived from the meaning and scope of the claims and equivalent concepts thereof are included in the scope of the disclosure.

What is claimed is:

1. A display device comprising:
a substrate;
a plurality of light emitting elements disposed on the substrate and generating light; and
a bank portion disposed on the substrate, protruding from the substrate, and adjacent to at least one of the plurality of light emitting elements, wherein
the plurality of light emitting elements comprises:
a first light emitting element generating light of a first color and including an inorganic material; and
a second light emitting element generating light of a second color different from the first color, the second light emitting element including an organic material, and
the bank portion is disposed between the first light emitting element and the second light emitting element.

2. The display device of claim 1, further comprising:
an encapsulation layer covering the plurality of light emitting elements,
wherein the encapsulation layer comprises:
a first encapsulation layer covering the second light emitting element and including an organic material; and
a second encapsulation layer covering the first light emitting element.

3. The display device of claim 2, wherein the bank portion surrounds the first encapsulation layer in a plan view.

4. The display device of claim 2, wherein
the first encapsulation layer defines an opening overlapping the first light emitting element, and
the bank portion is disposed around the opening.

5. The display device of claim 2, further comprising:
a first capping layer disposed on the bank portion, the first capping layer being disposed under the first encapsulation layer and under the second encapsulation layer; and
a second capping layer disposed on the first capping layer and the first encapsulation layer, the second capping layer being disposed under the second encapsulation layer.

6. The display device of claim 5, wherein
the first capping layer extends along a surface shape of the bank portion, and
the second capping layer extends along a surface shape of the first capping layer on the bank portion.

7. The display device of claim 6, wherein a contact area between the first capping layer and the second capping layer in an area is greater than a planar area of the area where the bank portion is disposed.

8. The display device of claim 1, wherein the bank portion includes a first bank having a continuous shape.

9. The display device of claim 8, wherein the bank portion further includes a second bank disposed on at least one of an inside and an outside of the first bank.

10. The display device of claim 9, wherein the second bank includes two or more sub banks, and the two or more sub banks are spaced apart from each other.

11. The display device of claim 9, further comprising:
a filling layer filling a groove between the first bank and the second bank.

12. The display device of claim 11, wherein the filling layer includes at least one material selected from an inorganic oxide and a complex compound.

13. A method of manufacturing a display device, the method comprising:
forming a bank portion protruding from a substrate on the substrate; and
forming a plurality of light emitting elements at a position adjacent to the bank portion on the substrate, wherein
the forming of the plurality of light emitting elements comprises:
forming a first light emitting element including an inorganic material that generates light of a first color; and
forming a second light emitting element including an organic material that generates light of a second color different from the first color, and
the first light emitting element and the second light emitting element are formed with the bank portion disposed therebetween.

14. The method of claim 13, further comprising:
forming a first encapsulation layer on the second light emitting element and the bank portion after the forming of the second light emitting element and before the forming of the first light emitting element; and
removing the first encapsulation layer in an area spaced apart from the second light emitting element by the bank portion after the forming of the second light emitting element and before the forming of the first light emitting element.

15. The method of claim 14, further comprising:
forming a second encapsulation layer on the first light emitting element after the forming of the first light emitting element.

16. The method of claim 15, further comprising:
forming a first capping layer on the second light emitting element and on the bank portion before the forming of the first encapsulation layer,
wherein the first capping layer covers a surface of the bank portion.

17. The method of claim 16, further comprising:
forming a second capping layer on the first encapsulation layer and on the first capping layer before the forming of the first light emitting element,
wherein the second capping layer covers the first capping layer that is disposed on the bank portion.

18. The method of claim 17, wherein the forming of the bank portion comprises forming a first bank having a continuous shape.

19. The method of claim 18, wherein the forming of the bank portion further comprises:
forming a second preliminary bank disposed on at least one of an inside and an outside of the first bank; and
forming a second bank by partially removing the second preliminary bank.

20. The method of claim 19, further comprising:
forming a filling layer filling a groove between the first bank and the second bank after the forming of the first capping layer and before the forming of the second capping layer.
